(19) United States
(12) Patent Application Publication
(10) Pub. No.: US 2025/0358538 A1
(43) Pub. Date: Nov. 20, 2025

(54) SOLID-STATE IMAGING ELEMENT AND IMAGING DEVICE

(71) Applicant: SONY SEMICONDUCTOR SOLUTIONS CORPORATION, KANAGAWA (JP)

(72) Inventor: TOSHIAKI ONO, KANAGAWA (JP)

(21) Appl. No.: 18/871,492

(22) PCT Filed: Jun. 6, 2023
(86) PCT No.: PCT/JP2023/021064

§ 371 Date: Dec. 4, 2024

(30) Foreign Application Priority Data
Jun. 15, 2022 (JP) 2022-096868

(51) Int. Cl. H04N 25/571; H04N 25/616; H04N 25/78

(52) U.S. Cl. CPC H04N 25/571; H04N 25/78; H04N 25/616

(57) ABSTRACT

[Object] To provide a solid-state imaging element and an imaging device that can enlarge the dynamic range and convert even a small amount of photoelectrically-converted electric charges into an image signal. [Solving Means] According to the present disclosure, provided is a solid-state imaging element including a photoelectric conversion unit that generates electric charges according to an amount of received light, a first electric charge holding unit that is connected to the photoelectric conversion unit via a first node, a comparator that outputs a first signal when a potential of the first node and a predetermined potential coincide with each other, a reset unit that sets the first node to a reset potential according to the first signal, and a counting unit that counts and outputs the first signal, and in a first mode, the reset potential applied to the first node changes in time series.

### TECHNICAL FIELD

The present disclosure relates to a solid-state imaging element and an imaging device.

### BACKGROUND ART

In a solid-state imaging element, a method of enlarging the dynamic range regardless of the accumulation capacity for accumulating the electric charges of a photoelectric conversion unit is generally known. In the method of enlarging the dynamic range, the dynamic range is enlarged by counting the number of times the photoelectrically-converted electric charge amount exceeds a threshold value.

However, electric charges that do not exceed the threshold value are not detected as signal electric charges, so that the signal is deteriorated as the illumination becomes low. In addition, there is a risk that the threshold value varies for each pixel circuit.

### CITATION LIST

### Patent Literature

### [PTL 1]

Japanese Patent Laid-open No. 2021-114742

### SUMMARY

### Technical Problem

Therefore, the present disclosure provides a solid-state imaging element and an imaging device that can enlarge the dynamic range and convert even a small amount of photoelectrically-converted electric charges into an image signal.

### Solution to Problem

In order to solve the above-described problem, according to the present disclosure, provided is a solid-state imaging element including a photoelectric conversion unit that generates electric charges according to an amount of received light, a first electric charge holding unit that is connected to the photoelectric conversion unit via a first node, a comparator that outputs a first signal when a potential of the first node and a predetermined potential coincide with each other, a reset unit that sets the first node to a reset potential according to the first signal, and a counting unit that counts and outputs the first signal, and in a first mode, the reset potential applied to the first node changes in time series.

In a second mode, the reset potential having a fixed value may be applied.

The reset unit may include a reset transistor connected between the first node and a power supply unit, the comparator may maintain an output of the first signal in a case where the potential of the first node exceeds the predetermined potential to a low potential side, the reset unit may cause the reset transistor to be in a conductive state during the output of the first signal, and the potential of the power supply unit may be so raised as to exceed the predetermined potential from the low potential side relative to the predetermined potential, in the first mode.

A read-out circuit that reads out the potential of the first node may further be provided.

An analog-digital conversion unit that generates a digital signal in reference to an analog signal supplied from the read-out circuit and a signal processing unit that generates an image signal corresponding to an electric charge amount generated by the photoelectric conversion unit according to the count, the digital signal, and a predetermined coefficient may further be provided.

The signal processing unit may change a value of the predetermined coefficient in reference to the digital signal obtained in the first mode.

A plurality of potentials that are different in speed at which the potential applied to the first node changes in time series may be applied and a plurality of the predetermined coefficients may be generated in reference to a plurality of the digital signals in the first mode, and the signal processing unit may change the value of the predetermined coefficient in reference to the plurality of digital signals in the second mode.

In the second mode, the signal processing unit may change the value of the predetermined coefficient according to the count.

A second electric charge holding unit that is connected to the first node in parallel with the first electric charge holding unit may further be provided.

The first electric charge holding unit may be connected to the first node via a second transistor, the conductive state of the second transistor may be set to a first state in a first period of the second mode, and in a case where the electric charges accumulated in the second electric charge holding unit exceed a predetermined capacity, the electric charges may be accumulated in the first electric charge holding unit.

The second transistor may enter a state of higher conductivity than the first state during the output of the first signal and may enter a non-conductive state when the output of the first signal is stopped in the first mode, and the signal processing unit may change, in the second mode, the value of the predetermined coefficient in reference to the digital signal obtained in the non-conductive state in the first mode. A current to be supplied to the comparator may be controlled according to the potential of the second electric charge holding unit.

In order to solve the above-described problem, according to the present disclosure, provided is a solid-state imaging device that includes the solid-state imaging element and an optical system.

### BRIEF DESCRIPTION OF DRAWINGS

FIG. 1 is a block diagram for depicting a configuration example of an imaging device in a first embodiment of the present technique.

FIG. 2 is a block diagram for depicting a configuration example of a solid-state imaging element in the present embodiment.

FIG. 3 is a diagram for schematically depicting a connection between a pixel circuit and a processing circuit.

FIG. 4 is a diagram for depicting a configuration example of a first substrate and a second substrate.

FIG. 5 is a block diagram for depicting a configuration example of the pixel circuit.

FIG. 6 is a diagram for depicting a circuit configuration example of the pixel circuit.

FIG. 7 is a block diagram for depicting a configuration example of a read-out circuit in the first embodiment of the present technique.

FIG. 8 depicts time charts of an operation example in a normal mode according to the present embodiment.

FIG. 9 depicts time charts of an operation example in a case where an amount of light abruptly changes during exposure.

FIG. 10 is a time chart of an operation example in a calibration mode according to the present embodiment.

FIG. 11 is a time chart of an operation example in a calibration mode according to a second embodiment.

FIG. 12 is a block diagram for depicting a configuration example of a pixel circuit according to the second embodiment.

FIG. 13 is a diagram for depicting a circuit configuration example of a pixel circuit according to a third embodiment.

FIG. 14 depicts time charts of an operation example according to the third embodiment.

FIG. 15 is a time chart of an operation example in a calibration mode according to the third embodiment.

FIG. 16 is a diagram for depicting a configuration example of a pixel circuit according to a fourth embodiment.

FIG. 17 depicts time charts of an operation example according to the fourth embodiment.

FIG. 18 is a diagram for schematically depicting a part of the imaging element.

FIG. 19 is a block diagram depicting an example of schematic configuration of a vehicle control system.

FIG. 20 is a diagram of assistance in explaining an example of installation positions of an outside-vehicle information detecting section and an imaging section.

### DESCRIPTION OF EMBODIMENTS

Hereinafter, embodiments of a solid-state imaging element and an imaging device will be described with reference to the drawings. In the following, main configuration parts of the solid-state imaging element and the imaging device will mainly be described, but configuration parts and functions that are not illustrated or described may exist in the solid-state imaging element and the imaging device. The following description does not exclude configuration parts and functions that are not illustrated or described.

### First Embodiment

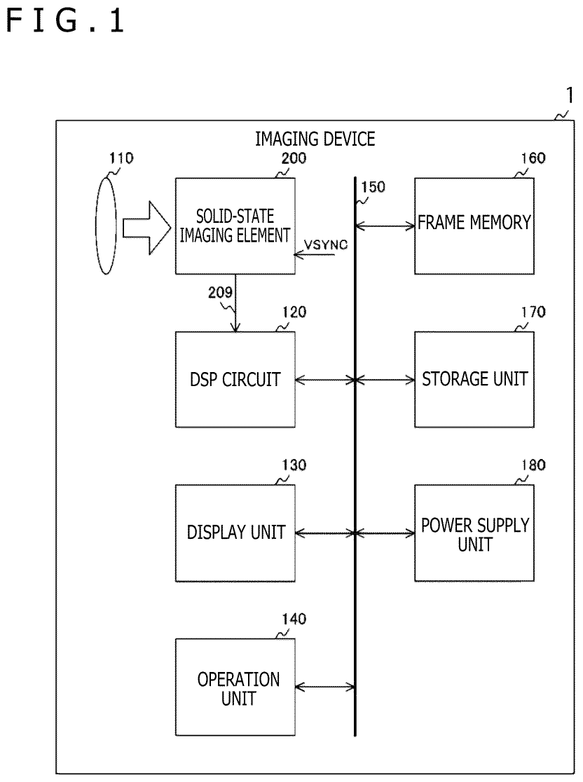

FIG. 1 is a block diagram for depicting a configuration example of an imaging device 1 in a first embodiment of the present technique. The imaging device 1 is a device for capturing image data, and includes an optical unit 110, a solid-state imaging element 200, and a DSP (Digital Signal Processing) circuit 120. The imaging device 1 further includes a display unit 130, an operation unit 140, a bus 150, a frame memory 160, a storage unit 170, and a power supply unit 180. As the imaging device 1, a camera mounted on a smartphone, an on-vehicle camera, or the like is assumed.

The optical unit 110 collects light from a subject and guides it to the solid-state imaging element 200. The solid-state imaging element 200 generates image data by photoelectric conversion. The solid-state imaging element 200 supplies the generated image data to the DSP circuit 120 via a signal line 209. The optical unit 110 includes, for example, a plurality of lenses and configures an optical system.

The DSP circuit 120 executes predetermined signal processing on the image data. The DSP circuit 120 outputs the processed image data to the frame memory 160 or the like via the bus 150.

The display unit 130 displays image data. As the display unit 130, for example, a liquid crystal panel or an organic EL (Electro Luminescence) panel is assumed. The operation unit 140 generates an operation signal according to an operation performed by the user.

The bus 150 is a common path through which the optical unit 110, the solid-state imaging element 200, the DSP circuit 120, the display unit 130, the operation unit 140, the frame memory 160, the storage unit 170, and the power supply unit 180 exchange data with each other.

The frame memory 160 holds image data. The storage unit 170 stores various kinds of data such as image data. The power supply unit 180 supplies power to the solid-state imaging element 200, the DSP circuit 120, the display unit 130, and the like.

### Configuration Example of Solid-State Imaging Element

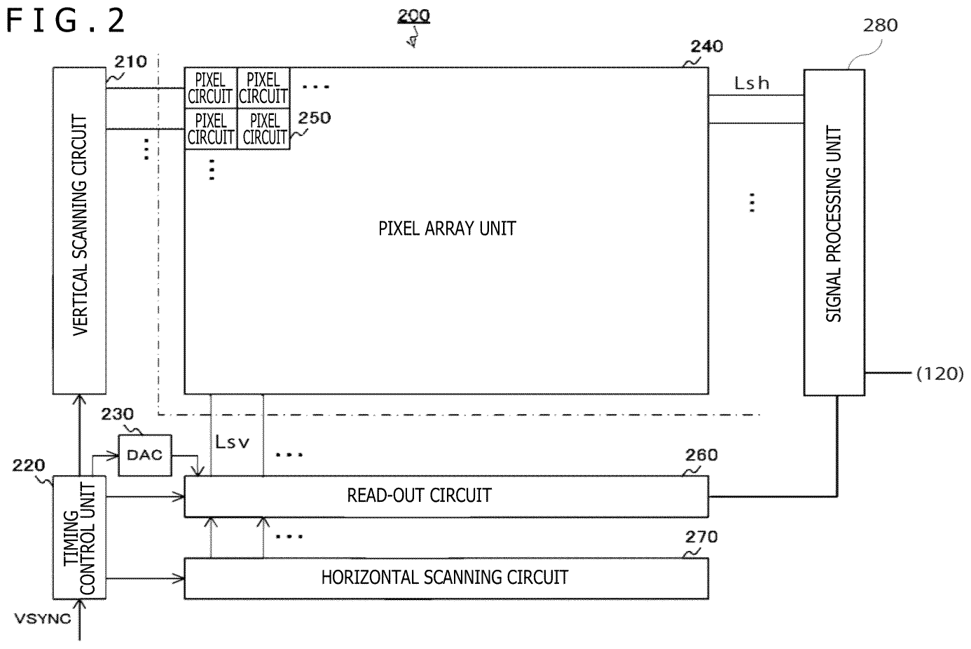

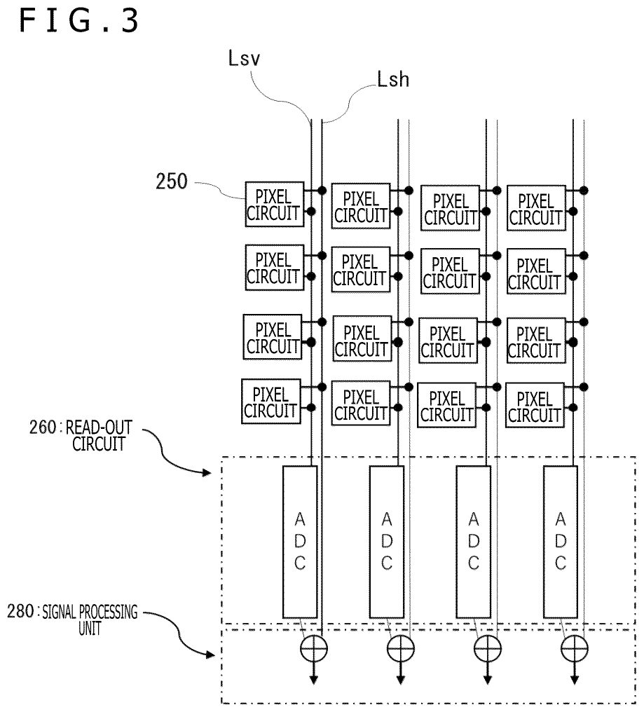

FIG. 2 is a block diagram for depicting a configuration example of the solid-state imaging element 200 in the present embodiment. FIG. 3 is a diagram for schematically depicting a connection between a pixel circuit and a processing circuit.

As depicted in FIG. 2 and FIG. 3, the solid-state imaging element 200 includes a vertical scanning circuit 210, a timing control unit 220, a DAC (Digital to Analog Converter) 230, a pixel array unit 240, a read-out circuit 260, a horizontal scanning circuit 270, and a signal processing unit 280. In the pixel array unit 240, a plurality of pixel circuits 250 are arranged in a two-dimensional lattice shape.

The vertical scanning circuit 210 sequentially selects and drives rows in the pixel array unit 240. The timing control unit 220 controls the operation timings of the vertical scanning circuit 210, the DAC 230, the read-out circuit 260, and the horizontal scanning circuit 270 in synchronization with a vertical synchronization signal VSYNC.

The DAC 230 generates a sawtooth waveform-like ramp signal and supplies it to the read-out circuit 260 as a reference signal.

The pixel circuit 250 is a circuit for performing photoelectric conversion according to the control of the vertical scanning circuit 210. The pixel circuit 250 counts the number of times a photoelectrically-converted electric charge amount exceeds a threshold value, and outputs a digital signal including the count number to the signal processing unit 120 via a horizontal signal line Lsh. In addition, a pixel 100 outputs an analog remaining electric charge signal related to remaining electric charges to the read-out circuit 260 via a vertical signal line Lsv as an analog pixel signal.

In the read-out circuit 260, an ADC (see FIG. 3) is arranged for each column of the pixel circuits 250. Each of the ADCs converts a pixel signal of the corresponding column into a digital signal and outputs it to the signal processing unit 280 according to the control of the horizontal scanning circuit 270. The horizontal scanning circuit 270 controls the read-out circuit 260 causes the read-out circuit 260 to sequentially output the digital signals. It should be noted that, in the present embodiment, a readout circuit 260 is referred to as a read-out circuit 260 in some cases.

The signal processing unit 280 generates an image signal value of each pixel 100 by using the counter value of each pixel 100 in the pixel array unit 240 and the remaining electric charge signal value of each pixel 100 supplied from the read-out circuit 260. The signal processing unit 280 outputs the image signal value of each pixel 100 to the DSP circuit 120.

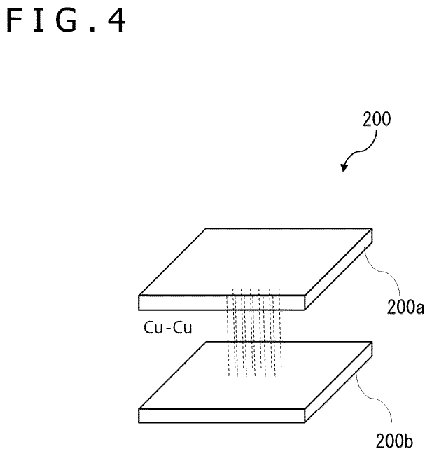

FIG. 4 is a diagram for depicting a configuration example of a first substrate and a second substrate. As depicted in FIG. 4, a first substrate 200a and a second substrate 200b have a laminated structure. In addition, the first substrate 200a and the second substrate 200b are connected by, for example, Cu-Cu wiring. The connection may be made by a connection part such as a via or a bump.

### Configuration Example of Pixel Circuit

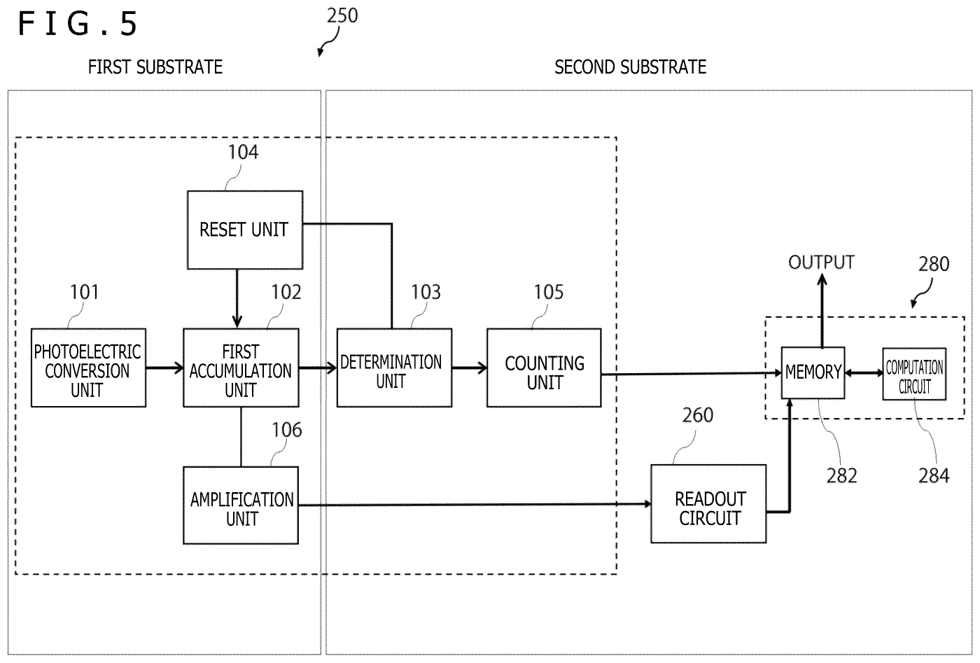

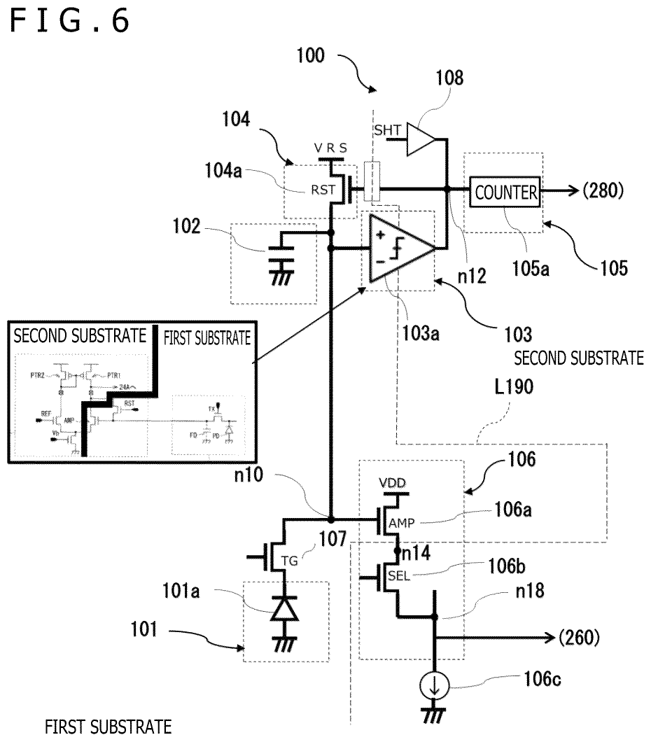

A configuration example of the pixel circuit 250 in the present embodiment will be described using FIG. 5 and FIG. 6. FIG. 5 is a block diagram for depicting a configuration example of the pixel circuit 250. The pixel circuit 250 has a photoelectric conversion unit 101, a first accumulation unit 102, a determination unit 103, a reset unit 104, a counting unit 105, and an amplification unit 106. In addition, the signal processing unit 280 has a memory 282 and a computation unit 284.

As depicted in FIG. 5, the photoelectric conversion unit 101, the first accumulation unit 102, the reset unit 104, and the amplification unit 106 are configured on the first substrate 200a (see FIG. 4). Meanwhile, the determination unit 103, the counting unit 105, the amplification unit 106, the read-out circuit 260, and the signal processing unit 280 are configured on the second substrate 200b. Accordingly, it is possible to further downsize the imaging element 200.

The photoelectric conversion unit 101 generates electric charges according to the received light. The photoelectric conversion unit 101 has a predetermined electrostatic capacity. The first accumulation unit 102 accumulates electric charges exceeding the predetermined electrostatic capacity of the photoelectric conversion unit 101.

The determination unit 103 determines whether or not the potential of the first accumulation unit 102 has reached a predetermined value, and outputs a first signal to the reset unit 104 and the counting unit 105 in the case where the potential has reached the predetermined value. The reset unit 104 resets the first accumulation unit 102 according to the first signal and discharges the accumulated electric charges of the first accumulation unit 102.

The counting unit 105 counts the number of times the first signal is input and outputs the count to the memory 282 of the signal processing unit 280. The memory 282 stores the counter number in a storage area corresponding to the coordinate of each pixel circuit 250. It should be noted that the initial value after the reset of the counting unit 105 is 0.

The amplification unit 106 outputs an analog remaining electric charge signal corresponding to the remaining electric charges of the first accumulation unit 102 remaining without being reset to the read-out circuit 260.

As described above, when the electric charges generated by the photoelectric conversion unit 101 are accumulated in the first accumulation unit 102 and the determination unit 103 determines to be a predetermined potential, the reset operation of the first accumulation unit 102 is performed. The counting unit 105 counts this as 1 count. The first accumulation unit 102 starts the accumulation again. Such processing is repeated in an accumulation period.

Further, after the end of the accumulation period, the amplification unit 106 outputs the analog remaining electric charge signal corresponding to the remaining electric charges accumulated in the first accumulation unit 102 to the read-out circuit 260. The read-out circuit 260 outputs a digital signal Sa corresponding to the analog remaining electric charges to the memory 282 of the signal processing unit 280. The memory 282 stores the digital signal Sa in a storage area corresponding to the coordinate of each pixel circuit 250.

The potential at the time of the reset accumulated in the first accumulation unit 102 and the accumulated electric charge amount are associated with each other in advance. Accordingly, the electric charge amount generated during the accumulation period is [the accumulated electric charge amount of the first accumulation unit]×[the number of reset times]. Further, the analog remaining electric charge signal corresponding to the electric charges remaining in the first accumulation unit in a read-out period is output to the read-out circuit 260. Accordingly, the final generated electric charge amount is [the accumulated electric charge amount of the first accumulation unit]×[the number of reset times]+[the remaining electric charge amount].

A computation unit 280b of the signal processing unit 280 computes a first image signal corresponding to [the accumulated electric charge amount of the first accumulation unit]×[the number of reset times] as K1×[the number of reset times], and computes a second image signal corresponding to [the remaining electric charge amount] as K2×[the value of the digital signal Sa]. That is, the computation unit 280b of the signal processing unit 280 computes K1×[the number of reset times]+K2×[the value of the digital signal Sa] as an image signal G (x, y) of the pixel circuit 250, and outputs it to the memory 282. K1 and K2 are freely-selected coefficients to match the dimensions. The coordinate (x, y) is the positional coordinate of the pixel circuit 250, and corresponds to the read-out row and the read-out column of the pixel array unit 240.

The memory 282 stores the image signal G (x, y) in a storage area corresponding to the coordinate (x, y) of each pixel circuit 250. Further, the memory 282 outputs the image signal G (x, y) corresponding to the coordinate of each pixel circuit 250 to the DSP circuit 120 as image data.

FIG. 6 is a diagram for depicting a circuit configuration example of the pixel circuit 250. The photoelectric conversion unit 101 includes a photoelectric conversion element 101a, and the first accumulation unit 102 includes a first electricity accumulation unit 102. The first electricity accumulation unit 102 is, for example, a floating diffusion (FD). FIG. 6 further illustrates a circuit configuration configured on the first substrate (see FIG. 4) and a circuit configuration configured on the second substrate (see FIG. 4). It should be noted that the first accumulation unit 102 according to the present embodiment corresponds to a first electric charge holding unit.

In addition, the determination unit 103 includes a comparator 103a, the reset unit 104 includes a reset transistor 104a, and the counting unit 105 includes a counter 105a. Further, the amplification unit 106 has an amplifying transistor 106a and a selecting transistor 106b. That is, as depicted in FIG. 6, the pixel circuit 250 has the photoelectric conversion element 101a, the first electricity accumulation unit 102, the comparator 103a, the reset transistor 104a, the counter 105a, the amplifying transistor 106a, the selecting transistor 106b, a transfer transistor 107, and an amplifier 108.

The reset transistor 104a, the amplifying transistor 106a, the selecting transistor 106b, and the transfer transistor 107 include, for example, N-channel MOS transistors. Further, drive signals TG, RST, and SEL are supplied to the gate electrodes thereof. These drive signals are pulse signals in which the state of a high level is an active state (ON state) and the state of a low level is an inactive state (OFF state).

As depicted in FIG. 6, the photoelectric conversion element 101a includes, for example, a PN-junction photodiode, receives light from a subject, generates electric charges corresponding to the amount of received light by photoelectric conversion, and accumulates them.

The transfer transistor 107 is connected between the photoelectric conversion element 101a and the first electricity accumulation unit 102 via a node n10. In response to the drive signal TG applied to the gate electrode of the transfer transistor 107, the remaining electric charges accumulated in the photoelectric conversion element 101a are transferred to the first electricity accumulation unit 102. It should be noted that, in the present embodiment, the drive signal TG is driven in the state of a low level during the accumulation of electric charges, but the accumulated electric charges are accumulated in the first electricity accumulation unit 102 as leakage electric charges via the transfer transistor 107.

The input terminal of the comparator 103a is connected to the node n10, and the output terminal thereof is connected to the gate electrode of the reset transistor 104a via a node n12. The comparator 103a outputs the first signal when the potential of the node n10 exceeds a predetermined threshold potential Vth downward. The first signal is a high level signal, but becomes a low level signal when the first electricity accumulation unit 102 is reset, and thus becomes a pulse signal.

The reset transistor 104a is an element for appropriately initializing (resetting) the first electricity accumulation unit 102, the drain thereof is connected to a transformer power supply VRS, and the source thereof is connected to the first electricity accumulation unit 102 via the node n10. The first signal is applied to the gate electrode of the reset transistor 104a as the drive signal RST. When the drive signal RST is applied, the reset transistor 104a enters a conductive state, and the potential of the node n10 is reset to the potential level of the transformer power supply VRS. It should be noted that the potential of the transformer power supply VRS becomes a power supply potential VDD as a constant potential at the time of a “normal mode operation” to be described later. In contrast, the potential of the transformer power supply VRS changes in time series at the time of a “calibration mode operation” to be described later. In addition, the potential of the transformer power supply VRS according to the present embodiment corresponds to the reset potential.

The input terminal of the counter 105a is connected to the output terminal of the comparator 103a via the node n12, and the output terminal thereof is connected to the signal processing unit 120. The counter 105a adds 1 to the counter every time the first signal is input, and outputs the result to the signal processing unit 280.

The gate electrode of the amplifying transistor 106a is connected to the first electricity accumulation unit 102 via the node n10, the drain thereof is connected to the power supply of the power supply potential VDD, and the amplifying transistor 106a serves as an input part of a source follower circuit for reading out the remaining electric charges of the first electricity accumulation unit 102 and the photoelectric conversion unit 101. That is, the source of the amplifying transistor 106a is connected to the vertical signal line Lsv via the selecting transistor 106b, configuring a source follower circuit with a constant current source 106c connected to one end of the vertical signal line Lsv.

The selecting transistor 106b is connected between the source of the amplifying transistor 106a and the vertical signal line, and the drive signal SEL is supplied to the gate electrode of the selecting transistor 106b as a selection signal. When the drive signal SEL is in an active state, the selecting transistor 106a enters a conductive state, and the pixel provided with the selecting transistor 106a enters a selected state. When the pixel is in a selected state, the signal output from the amplifying transistor 106a is read out to the read-out circuit 260 via the vertical signal line Lsv.

The amplifier circuit 108 supplies an initialization signal SHT to the node n12. When the counter 105 receives the initialization signal SHT, the counter value is initialized to 0. In addition, in each pixel 250, a plurality of drive lines are wired for, for example, each pixel row. Further, the drive signals TRG, RST, SEL, and SHT are supplied from the vertical scanning circuit 210 to the inside of the pixels through the plurality of drive lines as pixel drive lines.

### Configuration Example of Column Signal Processing Unit

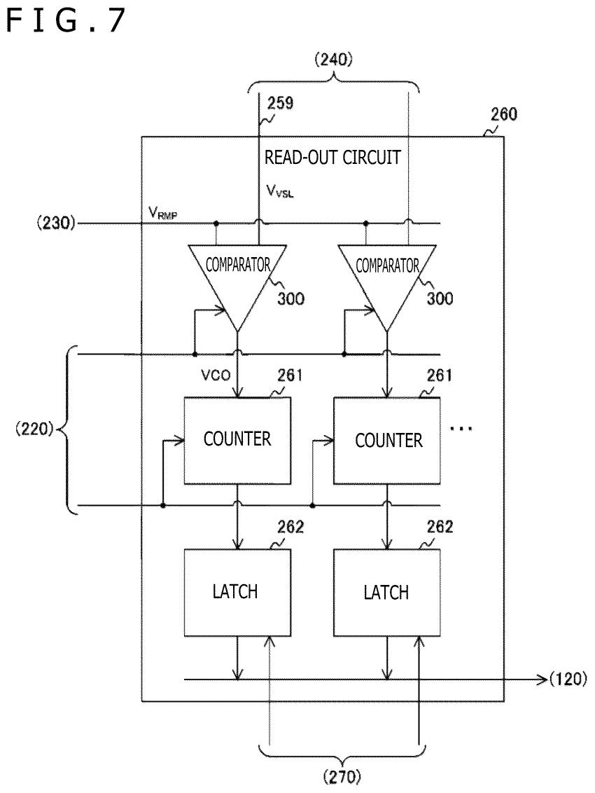

FIG. 7 is a block diagram for depicting a configuration example of the read-out circuit 260 in the first embodiment of the present technique. In the read-out circuit 260, a comparator 300, a counter 261, and a latch 262 are arranged for each column. In the case where the number of columns is N (N is an integer), N pieces of comparators 300, N pieces of counters 261, and N pieces of latches 262 are arranged. It should be noted that a set of the comparator 300, the counter 261, and the latch 262 according to the present embodiment corresponds to the ADC.

The comparator 300 compares a reference signal from the DAC 230 with a pixel signal from the corresponding column. Hereinafter, the potential of the reference signal is referred to as a reference potential VRMP, and the potential of a vertical signal line 259 for transmitting the pixel signal is referred to as an input potential VVSL. The comparator 300 supplies an output signal VCO indicating the comparison result to the counter 261 of the corresponding column.

In addition, the level of the pixel signal (that is, the input potential VVSL) when the pixel circuit 250 is initialized is referred to as, for example, a “Vr level,” and the level of the pixel signal when the remaining electric charges accumulated in the photoelectric conversion element 101a are transferred to the node n10 is referred to as, for example, a “Vs level.” That is, in the present embodiment, a level serving as a comparison reference is referred to as the “Vr level” and a level to be compared with is referred to as the “Vs level” in some cases.

In addition, a case where information regarding the remaining electric charges (corresponding to the analog image signal) is included in both the level serving as the comparison reference and the level to be compared with is referred to as CDS (Correlated Double Sampling) driving in some cases. On the other hand, a driving example in the case where the information regarding the remaining electric charges (corresponding to the analog image signal) is not included in at least one of the level serving as the comparison reference and the level to be compared with is referred to as DDS (Double Data Sampling) driving in some cases. In general, the CDS driving tends to have a better SN ratio of the digital signal after digital conversion than the DDS driving.

The counter 261 counts a count value over a period until the output signal VCO is inverted. For example, the counter 261 counts down over a period until the output signal VCO corresponding to the reset level is inverted, and counts up over a period until the output signal VCO corresponding to the signal level is inverted. Accordingly, for example, processing of obtaining a difference between the Vr level and the Vs level is realized.

Further, the counter 261 causes the latch 262 to hold a digital signal indicating the count value. A/D conversion processing for converting an analog pixel signal into a digital signal is realized by the comparator 300 and the counter 261. That is, the comparator 300 and the counter 261 function as the ADC. The ADC using the comparator and the counter in such a manner is generally referred to as a single slope type ADC. The latch 262 holds a digital signal. The latch 262 outputs the held digital signal according to the control of the horizontal scanning circuit 270.

The solid-state imaging element 200 according to the present embodiment has a normal photographing mode and a calibration mode. The normal photographing mode is a mode having an exposure period and a read-out period and performing normal photographing. In contrast, the calibration mode is a mode in which information for calibrating the characteristic variation of each pixel circuit is acquired before the normal photographing. In the present embodiment, since an inversion threshold value varies for each pixel due to manufacturing variations of transistors in the calibration determination unit 103, the calibration mode is used to know the threshold value. Each mode is set according to an instruction input via the operation unit (140). In each mode, the drive signal supplied to each pixel circuit 250 via the vertical scanning circuit 210 is changed for each mode.

### Operation Example in Normal Mode

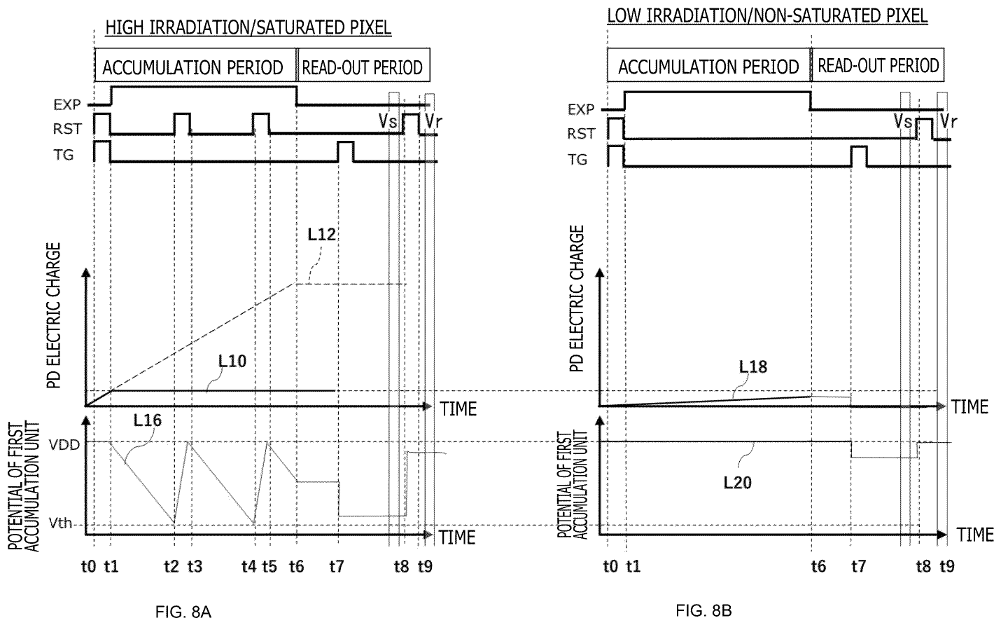

FIG. 8 depicts time charts of an operation example in the normal mode according to the present embodiment. FIG. 8A depicts an example of a state in which the counter 105a counts one or more times with high irradiation, and FIG. 8B depicts an example of a state in which the counter 105a does not count with low irradiation. The horizontal axis indicates time, and the vertical axis indicates the drive signals EXP, RST, and TG, the accumulated electric charges L10 of the photoelectric conversion element 101a, and the potential L16 of the first accumulation unit 102. The line L10 indicates the electric charges in the capacitor of the photoelectric conversion element 101a. The line L12 indicates the generated electric charge amount of the photoelectric conversion element 101a. A high level of the drive signal EXP indicates an electric charge accumulation period, and a low level thereof indicates a read-out period.

As depicted in FIG. 8A, in a high irradiation state, the drive signals RST and TG become a high level at time to, and the photoelectric conversion element 101a and the first accumulation unit 102 are initialized. That is, the potential of the node n10 becomes the power supply potential VDD.

Subsequently, at time t1, the drive signals RST and TG become a low level, and the drive signal EXP becomes a high level. Accordingly, the electric charges generated by the photoelectric conversion element 101a exceed the capacity and are accumulated in the first accumulation unit 102. Then, at time t1, the potential of the node n10 of the first accumulation unit 102 starts to decrease. Then, at time t2, the potential of the first accumulation unit 102 reaches the threshold potential Vth of the comparator 103a for the first time. Accordingly, the comparator 103a outputs the first signal, and the counter 105a adds 1 to the count value. At the same time, since the first signal that is the drive signal RST is at a high level, the reset transistor 104a enters a conductive state, and the potential of the node n10 of the first accumulation unit 102 is reset to the power supply potential VDD.

Such processing is repeated, and the drive signal EXP becomes a low level at time t6, and the read-out period is started. Subsequently, at time t7, the drive signal TG becomes a high level, the accumulated electric charges of the photoelectric conversion element 101a are transferred to the first accumulation unit 102, and the potential of the node n10 corresponds to the potential of the remaining electric charges. Then, at time t8, the drive signal RST becomes a high level, and the potential of the node n10 of one accumulation unit 102 is reset to the power supply potential VDD.

In addition, between times t7 and t8, the analog signal potential corresponding to the remaining electric charges is output to the read-out circuit 260 as the Vs level. Meanwhile, between times t8 and t9, the analog signal potential corresponding to a dark current is output to the read-out circuit 260 as the Vr level. Accordingly, the read-out circuit 260 converts the difference between the potential corresponding to the Vs level and the potential corresponding to the Vr level into the digital signal Sa, and outputs it to the signal processing unit 280.

Then, the computation unit 280b of the signal processing unit 280 computes K1×[the number of reset times: 2 times]+K2×[the value of the digital signal Sa] as the image signal G (x, y) of the pixel circuit 250, and outputs the result to the memory 282. The memory 282 stores the image signal G (x, y) in a storage area according to the coordinate (x, y) of each pixel circuit 250. Then, the memory 282 outputs the image signal G (x, y) corresponding to the coordinate of each pixel circuit 250 (x, y) to the DSP circuit 120 as image data.

In contrast, as depicted in FIG. 8B, in a low irradiation state, the drive signals RST and TG become a high level at time to, and the photoelectric conversion element 101a and the first accumulation unit 102 are initialized. That is, the potential of the node n10 becomes the power supply potential VDD.

Subsequently, at time t1, the drive signals RST and TG become a low level, and the drive signal EXP becomes a high level. Accordingly, electric charges are generated in the photoelectric conversion element 101a, and the electric charge amount L18 continues to increase, but the electric charge amount generated in the capacitor in the photoelectric conversion element 101a is maintained.

At time t6, the drive signal EXP becomes a low level, and the read-out period is started. Subsequently, at time t7, the drive signal TG becomes a high level, the accumulated electric charges of the photoelectric conversion element 101a are transferred to the first accumulation unit 102, and the potential of the node n10 corresponds to the potential of the remaining electric charges. Then, at time t8, the drive signal RST becomes a high level, and the potential of the node n10 of one accumulation unit 102 is reset to the power supply potential VDD.

In addition, between times t7 and t8, the analog signal potential corresponding to the remaining electric charges is output to the read-out circuit 260 as the Vs level. Meanwhile, between times t8 and t9, the analog signal potential corresponding to a dark current is output to the read-out circuit 260 as the Vr level. Accordingly, the read-out circuit 260 converts the difference between the potential corresponding to the Vs level and the potential corresponding to the Vr level into the digital signal Sa, and outputs it to the signal processing unit 280.

Then, the computation unit 280b of the signal processing unit 280 computes K1×[the number of reset times: 0 time]+K2×[the value of the digital signal Sa] as the image signal G (x, y) of the pixel circuit 250, and outputs the result to the memory 282. The memory 282 stores the image signal G (x, y) in a storage area corresponding to the coordinate (x, y) of each pixel circuit 250. Then, the memory 282 outputs the image signal G (x, y) corresponding to the coordinate (x, y) of each pixel circuit 250 to the DSP circuit 120 as image data.

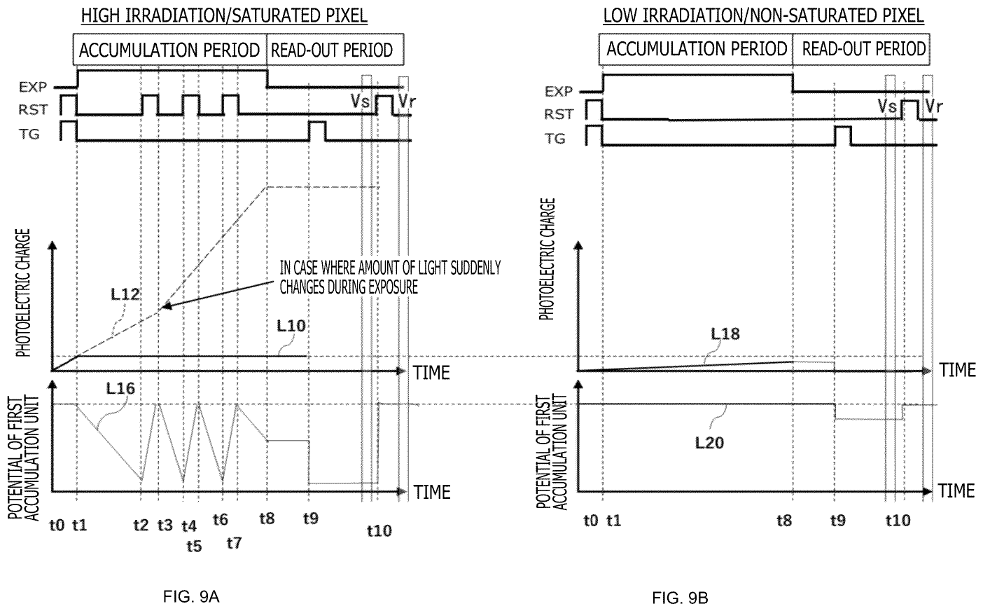

FIG. 9 depicts time charts of an operation example in the case where the amount of light abruptly changes during exposure. FIG. 9 depicts diagrams equivalent to those of FIG. 8 except the case where the amount of light abruptly changes. FIG. 9A depicts an example in which the counter 105a counts 3 times with high irradiation. As described above, in the case where the amount of light increases during exposure, the number of reset times increases, and the number is counted as it is. Hence, even in the case where the amount of light is constant or changed during exposure, the reset/count operation is performed following the situation, so that there is no risk of an error signal due to erroneous prediction. That is, the computation unit 280b of the signal processing unit 280 computes K1×[the number of reset times: 3 times]+K2×[the value of the digital signal Sa] as the image signal G (x, y) of the pixel circuit 250, and outputs it to the memory 282.

### Operation Example in Calibration Mode

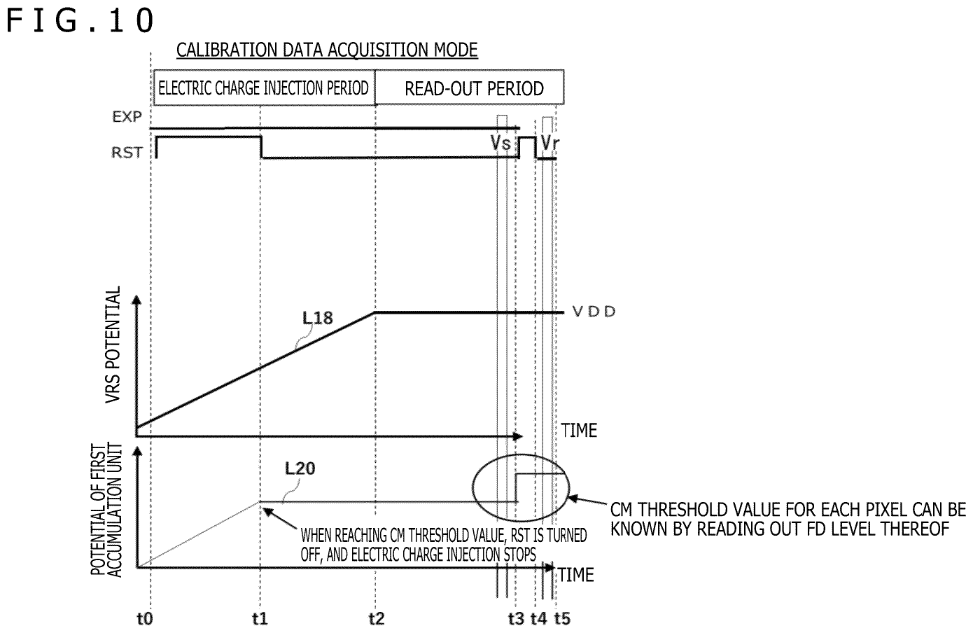

FIG. 10 is a time chart of an operation example in the calibration mode according to the present embodiment. The horizontal axis indicates time, and the vertical axis indicates the drive signals EXP and RST, the potential L18 of the transformer power supply VRS, and the potential L20 of the first accumulation unit 102.

As described above, the comparator 103a outputs the low level first signal until the potential of the node n10 (see FIG. 6) exceeds the threshold potential Vth downward, and outputs the high level first signal when the potential exceeds the threshold potential Vth downward. In addition, in the case where the first signal is at a high level, the reset transistor 104a outputs a high level signal. It should be noted that the potential of the node n10 (see FIG. 6) corresponds to the first electricity accumulation unit 102.

As depicted in FIG. 10, the potential L18 of the transformer power supply VRS starts to increase at time to. Since the potential of the node n10 at the time of start is in a state of exceeding the threshold potential Vth downward, the first signal is at a high level and the drive signal RST is at a high level. Since the drive signal RST is at a high level, the reset transistor 104a maintains a conductive state.

Further, when the potential L18 of the transformer power supply VRS continues to increase, the potential of the node n10 enters a state of exceeding the threshold potential Vth upward at time t1. Hence, the first signal changes to a low level, and the drive signal RST becomes a low level. Accordingly, the reset transistor 104a enters a non-conductive state. Thereafter, the potential L18 of the transformer power supply VRS continues to increase, but since the reset transistor 104a enters a non-conductive state, the potential of the node n10 is maintained in the state of the threshold potential Vth.

Then, the read-out period is started at time t2. In the read-out period, the potential L18 of the transformer power supply VRS is maintained at the power supply potential VDD. Then, at time t3, the drive signal RST becomes a high level signal by the output signal SHT of the amplifier circuit 108 (see FIG. 6), and the potential of the node n10 (see FIG. 6) is initialized to the power supply potential VDD.

At this time, between times t2 and t3, the potential of the node n10 corresponding to the threshold potential Vth is read out to the read-out circuit 260 as the Vs level. Meanwhile, between times t4 and t5, the potential of the node n10 corresponding to the power supply potential VDD is read out to the read-out circuit 260 as the Vr level. Accordingly, the difference between the potential at the Vs level and the potential at the Vr level is generated as the threshold potential Vth of the pixel 250. The memory 280 stores the threshold potential Vth for each coordinate (x, y) of the pixel circuit 250. Since the capacity of the first electricity accumulation unit 102 is known, the remaining electric charge amount corresponding to 1 count of the counter 105 can be accurately calculated from the information concerning the threshold potential Vth and the capacity of the first electricity accumulation unit 102. Accordingly, the coefficient K1 is calibrated and stored as K1 (x, y) for each coordinate (x, y) of the pixel circuit 250. That is, the image signal G (x, y) of the pixel circuit 250 can be more accurately computed as K1 (x, y)×[the number of reset times]+K2×[the value of the digital signal Sa].

As described above, according to the present embodiment, in the normal mode, the electric charges generated by the photoelectric conversion element 101a are accumulated in the first accumulation unit 102, and each time the predetermined threshold potential Vth is reached, the comparator 103a outputs the first signal to reset the first accumulation unit 102, and the counter 105a adds 1 to the count value. Accordingly, even in the case where the electric charges generated by the electric conversion element 101a exceed the capacitor of the first accumulation unit 102, the electric charges can be continuously accumulated in the first accumulation unit 102, and the electric charge amount generated by the photoelectric conversion element 101a can also be calculated from the count value. Further, the remaining electric charges of the electric conversion element 101a and the first accumulation unit 102 are read out to the read-out circuit 260 as an analog potential by the amplification unit 106 and converted into a digital value. As described above, the dynamic range is not saturated even with high irradiation, and the image signal including the remaining electric charges can be generated.

In addition, in the normal mode, even in the case where the capacity of the first accumulation unit 102 is never exceeded with low irradiation, the remaining electric charges of the electric conversion element 101a and the first accumulation unit 102 are read out to the read-out circuit 260 as an analog potential by the amplification unit 106 and converted into a digital value. Accordingly, the image signal including the remaining electric charges can be generated even in the case where the capacity of the first accumulation unit 102 is never exceeded with low irradiation.

Further, in the calibration mode, the potential L18 of the transformer power supply VRS is increased from the lower side of the threshold potential Vth. Accordingly, when the potential L18 of the transformer power supply VRS continues to increase, the potential of the node n10 enters a state of exceeding the threshold potential Vth upward, the reset transistor 104a enters a non-conductive state, and the potential of the node n10 is maintained in the state of the threshold potential Vth. Hence, information concerning the threshold potential Vth for each pixel circuit 250 can be obtained, and the coefficient K1 can be calibrated and stored as K1 (x, y) for each coordinate (x, y) of the pixel circuit 250. Accordingly, the image signal G (x, y) of the pixel circuit 250 can be more accurately computed as K1 (x, y)×[the number of reset times]+K2×[the value of the digital signal Sa].

### Second Embodiment

A solid-state imaging element 200 according to a second embodiment is different from the solid-state imaging element 200 according to the first embodiment in that the inclination of the potential change of the transformer power supply VRS is changed a plurality of times to execute the calibration mode. Hereinafter, the differences from the solid-state imaging element 200 according to the first embodiment will be described.

### Operation Example in Calibration Mode

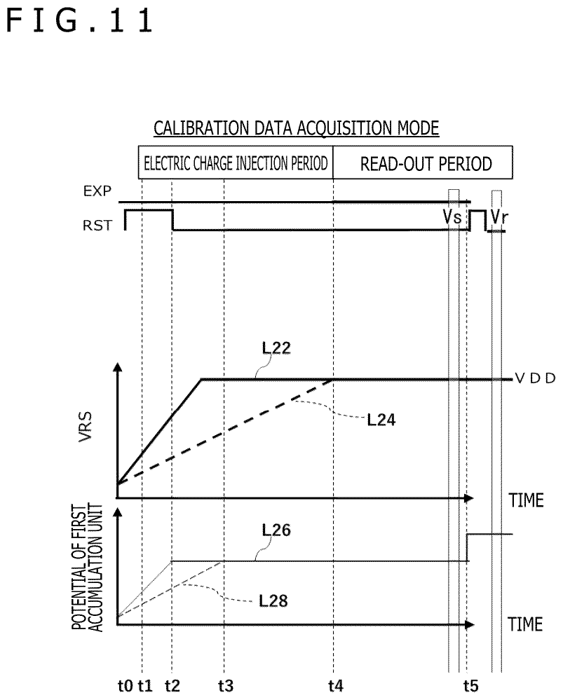

FIG. 11 is a time chart of an operation example in the calibration mode according to the present embodiment. The horizontal axis indicates time, and the vertical axis indicates the drive signals EXP and RST, the potentials L22 and 24 of the transformer power supply VRS, and the potentials L20 and L28 of the first accumulation unit 102. The potential L22 and the potential L26 indicate states in which the inclinations of the potential changes are larger than those of the potential L24 and the potential L28.

When the inclination of the potential change of the first accumulation unit 102 changes due to such characteristics as the operation delay of the comparator 103a, the determination threshold value changes in some cases. In preparation for this, in a calibration data acquisition mode, the sweep inclination of the transformer power supply VRS is changed to acquire calibration data a plurality of times.

In the case where the count value of the counter 105a is small, the amount of light is low, and the inclination of the potential change of the first accumulation unit becomes small, so that the value of the smaller inclination can be used for the calibration data. On the other hand, in the case where the count value is large, the amount of light is high, and thus calibration data with a larger inclination can be used. Accordingly, the signal processing unit 280 can follow even the variation of the determination threshold value caused by the change in the inclination of the potential of the first accumulation unit 102. It should be noted that the signal processing unit 280 may generate calibration data by interpolation or extrapolation according to the count value.

### Third Embodiment

A solid-state imaging element 200 according to a third embodiment is different from the solid-state imaging element 200 according to the first embodiment in that a second electricity accumulation unit is further provided. Hereinafter, the differences from the solid-state imaging element 200 according to the first embodiment will be described.

### Configuration Example of Pixel Circuit

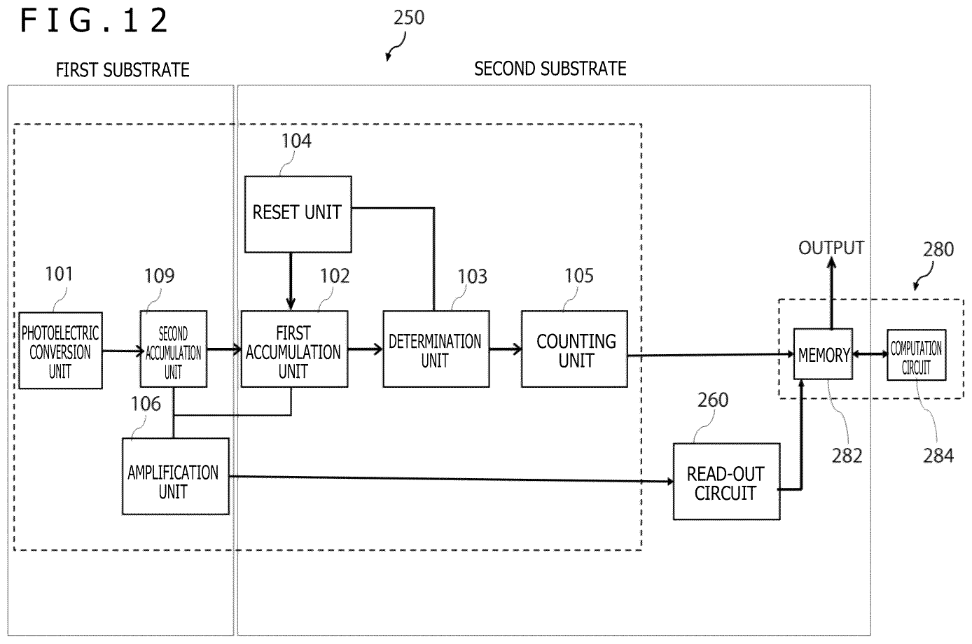

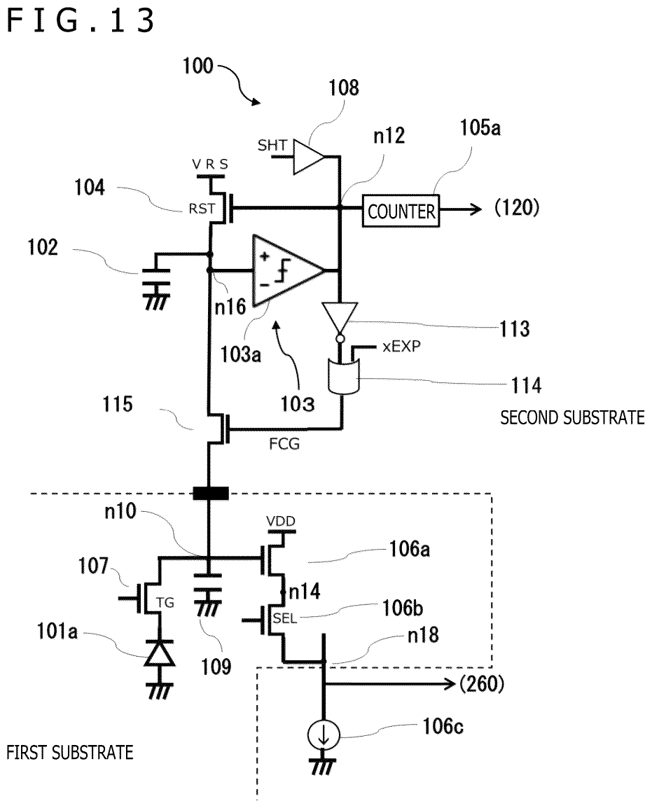

A configuration example of a pixel circuit 250 in the present embodiment will be described using FIG. 12 and FIG. 13. FIG. 12 is a block diagram for depicting a configuration example of the pixel circuit 250 according to the second embodiment. The pixel circuit 250 is different from the pixel circuit 250 according to the first embodiment in that a second electricity accumulation unit 109 is further provided. The capacitor capacity of the second electricity accumulation unit 109 is configured to be smaller than that of the first electricity accumulation unit 102. It should be noted that the second electricity accumulation unit 109 according to the present embodiment corresponds to a second electric charge holding unit.

As depicted in FIG. 12, the photoelectric conversion unit 101, the amplification unit 106, and the second electricity accumulation unit 109 are configured on the first substrate (see FIG. 4). Meanwhile, the first accumulation unit 102, the determination unit 103, the reset unit 104, the counting unit 105, the read-out circuit 260, and the signal processing unit 280 are configured on the second substrate (see FIG. 4). Accordingly, it is possible to further downsize the imaging element 200.

The second electricity accumulation unit 109 is connected in parallel with the first electricity accumulation unit 102 when the electric charges are accumulated. Accordingly, it is possible to increase the capacitor capacity for the accumulated electric charges when the electric charges are accumulated.

Meanwhile, when the remaining electric charges are read out, the first electricity accumulation unit 102 and the second electricity accumulation unit 109 are electrically disconnected from each other, and the electric charges of the photoelectric conversion unit 101 are transferred only to the second electricity accumulation unit 109.

FIG. 13 is a diagram for depicting a circuit configuration example of the pixel circuit 250 according to the third embodiment. The second electricity accumulation unit 109 is connected to a node n10. The second electricity accumulation unit 109 is, for example, a floating diffusion. A capacitor connection transistor 115 is connected between the node n10 and a node n16 to which the first electricity accumulation unit 102 is connected.

The capacitor connection transistor 115 includes, for example, an N-channel MOS transistor. A drive signal FCG is supplied to the gate electrode thereof. The drive signal is a pulse signal in which the state of a high level is an active state (ON state) and the state of a low level is an inactive state (OFF state).

An OR gate 114 is connected to the gate electrode of the capacitor connection transistor 115, and a NOT gate 113 is connected to the OR gate 114. A signal xEXP is a signal that becomes 0 in the accumulation period and becomes 1 in the read-out period. Accordingly, in the accumulation period, the drive signal FCG becomes a low level when the drive signal RST is at a high level. In addition, when the drive signal RST is at a high level, the drive signal FCG becomes an intermediate level signal. On the other hand, the drive signal FCG is always at a high level in the read-out period.

Accordingly, the capacitor connection transistor 115 is supplied with an intermediate level drive signal FDG when the electric charges are accumulated, and the electric charges overflowing the first electricity accumulation unit 102 are supplied to the second electricity accumulation unit 109.

Meanwhile, when the first electricity accumulation unit 102 is reset, a low level drive signal FDG is supplied to become an inactive state (Off state). Accordingly, the first electricity accumulation unit 102 and the second electricity accumulation unit 109 are electrically disconnected from each other.

### Operation Example in Normal Mode

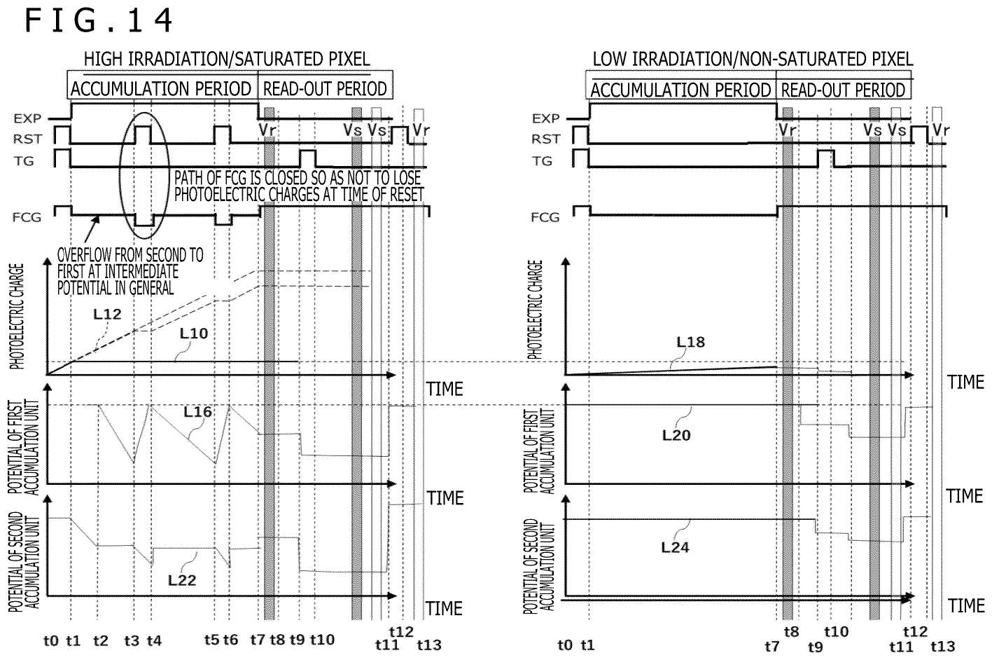

FIG. 14 depicts time charts of an operation example according to the third embodiment. FIG. 14A depicts an example of a state in which the counter 105a counts up one or more times with high irradiation, and FIG. 14B depicts an example of a state in which the counter 105a does not count up with low irradiation.

The horizontal axis indicates time, and the vertical axis indicates the drive signals EXP, RST, TG, and FCG, the accumulated electric charges L10 and L18 of the photoelectric conversion element 101a, the potentials L16 and L20 of the first accumulation unit 102, and the potentials L22 and L24 of the second accumulation unit 109.

As depicted in FIG. 14A, in a high irradiation state, the drive signals RST, TG, and FCG become a high level at time to, and the photoelectric conversion element 101a, the first accumulation unit 102, and the second accumulation unit 109 are initialized. That is, the potential of the node n10 becomes the power supply potential VDD. At this time, since the drive signal FCG is at a high level, the first accumulation unit 102 and the second accumulation unit 109 are connected in parallel and become the potential of the node n10.

Subsequently, at time t1, the drive signals RST and TG become a low level, the drive signal FCG becomes an intermediate level, and the drive signal EXP becomes a high level. Accordingly, the electric charges generated by the photoelectric conversion element 101a are accumulated in the second accumulation unit 109, and the potential L22 of the node n10 of the second accumulation unit 109 starts to decrease. Then, at time t2, a predetermined amount of electric charges is accumulated in the capacitor of the second accumulation unit 109, and the accumulation of electric charges in the first accumulation unit 102 is started. Accordingly, the potential L16 of the node n16 of the first accumulation unit 102 starts to decrease.

Then, at time t3, the threshold potential Vth of the comparator 103a is reached for the first time. Accordingly, the comparator 103a outputs the first signal, and the counter 105a adds 1 to the count value. At the same time, since the first signal that is the drive signal RST is at a high level, the reset transistor 104a enters a conductive state, and the potential of the node n16 of the first accumulation unit 102 is reset to the power supply potential VDD. In addition, at the same time, the drive signal FCG becomes a low level, the first accumulation unit 102 and the second accumulation unit 109 enter a non-conductive state, and the electric charges generated by the photoelectric conversion element 101a are accumulated in the second accumulation unit 109. As can be understood from this, the electric charges generated by the photoelectric conversion element 101a in the reset period of the first accumulation unit 102 are accumulated and maintained in the second accumulation unit 109.

Subsequently, at time t4, the drive signal RST becomes a low level again, and the drive signal FCG becomes an intermediate level. Accordingly, the electric charges generated by the photoelectric conversion element 101a are accumulated in the first accumulation unit 102, and the potential L16 of the node n16 of the first accumulation unit 102 starts to decrease again.

Such processing is repeated, the drive signal EXP becomes a low level at time t7, the read-out period is started, and the drive signal FCG becomes a high level. Since the drive signal FCG is at a high level, the capacitor connection transistor 115 enters a conductive state, the first accumulation unit 102 and the second accumulation unit 109 enter a conductive state, and the node n10 and the node n16 come to have the same potential.

Subsequently, at time t9, the drive signal TG becomes a high level, the accumulated electric charges of the photoelectric conversion element 101a are transferred to the first accumulation unit 102 and the second accumulation unit 109, and the potential of the node n10 corresponds to the potential of the remaining electric charges. Then, at time t10, the drive signal drive signal TG becomes a low level, and the photoelectric conversion element 101a is electrically disconnected from the first accumulation unit 102 and the second accumulation unit 109.

Subsequently, at time t12, the drive signal RST becomes a high level, and the first accumulation unit 102 and the second accumulation unit 109 are reset to the power supply potential VDD. Then, at time t13, the drive signal RST becomes a low level, and at time t14, the drive signal FCG becomes a low level.

In addition, between times t7 and t8, the analog remaining electric charge signals of the first accumulation unit 102 and the second accumulation unit 109 are output to a column signal processing unit 260 as the Vr level. Meanwhile, between times t10 and t11, the analog remaining electric charge signals of the first accumulation unit 102 and the second accumulation unit 109 to which the accumulated electric charges of the photoelectric conversion element 101a are added are output twice in time series to the column signal processing unit 260 as the Vs level. Accordingly, the column signal processing unit 260 converts the difference between the potential corresponding to the Vs level and the potential corresponding to the Vr level into a digital remaining electric charge signal Sa1, and outputs it to the signal processing unit 280. That is, the digital remaining electric charge signal Sa1 is a signal corresponding to the remaining electric charges of the photoelectric conversion element 101a. Since the capacity of the photoelectric conversion element 101a and the capacity of each of the first accumulation unit 102 and the second accumulation unit 109 are known, a value corresponding to the entire remaining electric charges at the end of the accumulation period can be computed from the digital remaining electric charge signal Sa1. As described above, the electric charges generated by the photoelectric conversion element 101a in the reset period of the first accumulation unit 102 are accumulated and maintained in the second accumulation unit 109. Hence, the digital remaining electric charge signal Sa1 also includes the electric charges generated by the photoelectric conversion element 101a in the reset period of the first accumulation unit 102.

Further, the computation unit 280b of the signal processing unit 280 computes K1×[the number of reset times: 2 times]+K4×[the signal value of the digital remaining electric charge signal Sa1] as the image signal G (x, y) of the pixel circuit 250, and outputs the result to the memory 282. The memory 282 stores the image signal in a storage area corresponding to the coordinate of each pixel circuit 250. Further, the memory 282 outputs the image signal G (x, y) corresponding to the coordinate of each pixel circuit 250 to the DSP circuit 120 as image data. K4 is a coefficient.

Further, between times t12 and t13, the analog remaining electric charge signals corresponding to the accumulated electric charges after the reset of the first accumulation unit 102 and the second accumulation unit 109 are output to the column signal processing unit 260 as the Vr level. Accordingly, the column signal processing unit 260 converts the difference between the potential corresponding to the Vs level and the potential corresponding to the Vr level into a digital remaining electric charge signal Sa2, and outputs it to the signal processing unit 280. That is, the digital remaining electric charge signal Sa2 is a signal corresponding to the entire remaining electric charges. Thus, the computation unit 280b of the signal processing unit 280 can compute K1×[the number of reset times: 2 times]+K5×[the signal value of the digital remaining electric charge signal Sa2] as the image signal G (x, y) of the pixel circuit 250. K5 is a coefficient. However, as described above, the image signal G (x, y) computed from the level signals at the first Vs level and Vr level has a better SN ratio.

Meanwhile, as depicted in FIG. 14B, in a low irradiation state, the drive signals RST, TG, and FCG become a high level at time to, and the photoelectric conversion element 101a, the first accumulation unit 102, and the second accumulation unit 109 are initialized. That is, the potential of the node n10 becomes the power supply potential VDD. At this time, since the drive signal FCG is at a high level, the first accumulation unit 102 and the second accumulation unit 109 are connected in parallel and become the potential of the node n10.

Subsequently, at time t1, the drive signals RST and TG become a low level, the drive signal FCG becomes an intermediate level, and the drive signal EXP becomes a high level. Accordingly, electric charges are generated by the photoelectric conversion element 101a, and the electric charge amount L18 continues to increase, but the electric charge amount generated in the capacitor in the photoelectric conversion element 101a is maintained. Therefore, the potentials L20 and L24 of the first accumulation unit 102 and the second accumulation unit 109 are maintained at VDD of the initial potential.

The driving in the read-out period is equivalent to that at the time of high irradiation. Accordingly, by the read-out of the first Vr level and Vs level, K1×[the number of reset times: 0 time]+K4×[the signal value of the digital remaining electric charge signal Sa1] is computed as the image signal G (x, y) of the pixel circuit 250, and output to the memory 282. The memory 282 stores the image signal in a storage area corresponding to the coordinate of each pixel circuit 250.

In addition, by the read-out of the second Vr level and Vs level, K1×[the number of reset times: 0 time]+K5×[the signal value of the digital remaining electric charge signal Sa2] is computed as the image signal G (x, y) of the pixel circuit 250.

### Operation Example in Calibration Mode

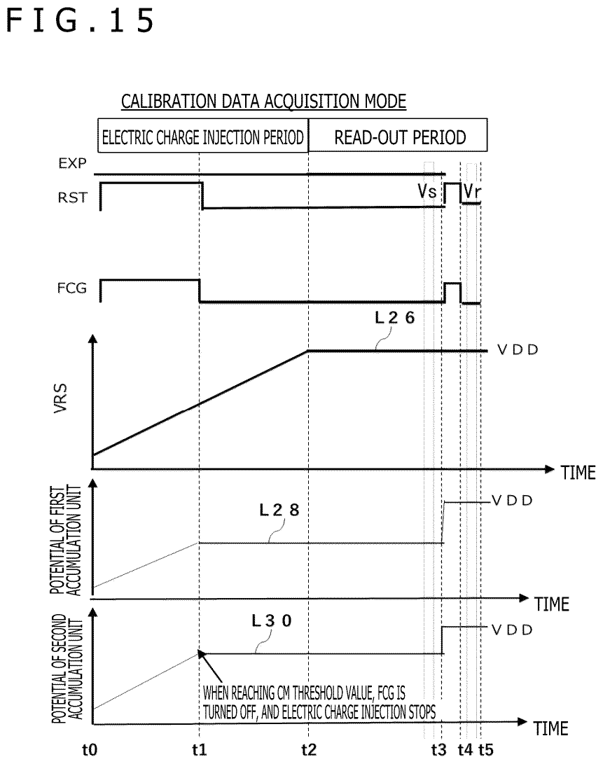

FIG. 15 is a time chart of an operation example in the calibration mode according to the third embodiment. The horizontal axis indicates time, and the vertical axis indicates the drive signals EXP, RST, and FCG, the potential L26 of the transformer power supply VRS, the potential L28 of the first accumulation unit 102, and the potential L30 of the second accumulation unit 109.

As described above, the comparator 103a outputs the low level first signal until the potential of the node n10 (see FIG. 6) exceeds the threshold potential Vth downward, and outputs the high level first signal when the potential of the node n10 exceeds the threshold potential Vth downward. In addition, in the case where the first signal is at a high level, the reset transistor 104a outputs a high level signal. It should be noted that the potential of the node n10 (see FIG. 6) corresponds to that of the first accumulation unit 102. In addition, the drive signal FCG is output as a high level signal in the case where the first signal is at a high level in the electricity accumulation period.

As depicted in FIG. 15, the potential L26 of the transformer power supply VRS starts to increase at time to. Since the potential of the node n16 at the time of start is in a state of exceeding the threshold potential Vth downward, the first signal becomes a high level, and the drive signal RST becomes a high level. Since the drive signal RST is at a high level, the reset transistor 104a maintains a conductive state.

Since the first signal is at a high level, the drive signal FCG becomes a high level signal. Since the drive signal FCG is at a high level, the capacitor connection transistor 105 maintains a conductive state.

Further, when the potential L26 of the transformer power supply VRS continues to increase, the potential of the node n16 becomes a state of exceeding the threshold potential Vth upward at time t1. Hence, the first signal changes to a low level, and the drive signal RST becomes a low level. Accordingly, the reset transistor 104a enters a non-conductive state.

Since the first signal is at a low level, the drive signal FCG becomes a low level signal at time t1. Since the drive signal FCG is a low level signal, the capacitor connection transistor 105 maintains a non-conductive state.

Thereafter, the potential L26 of the transformer power supply VRS continues to increase, but since the reset transistor 104a enters a non-conductive state, the potential of the node n16 is maintained in the state of the threshold potential Vth. As similar to the above, since the capacitor connection transistor 105 enters a non-conductive state, the potential of the node n10 is maintained in the state of the threshold potential Vth.

Then, the read-out period is started at time t2. Since the drive signal EXP is maintained at a low level, the drive signal FCG is maintained at a low level even in the read-out period. Accordingly, the potential of the node n16 is maintained in the state of the threshold potential Vth, and the potential of the node n10 is maintained in the state of the threshold potential Vth.

At time t3, the drive signal RST becomes a high level by the signal SHT of the amplifier 108, and the drive signal FCG also becomes a high level in synchronization. Accordingly, the first electricity accumulation unit 102 and the second electricity accumulation unit 109 are reset to the power supply potential VDD that is the initial potential, and the potentials of the node n16 and the node n10 are maintained at the power supply potential VDD.

At this time, the potential of the node n10 corresponding to the threshold potential Vth is read out to the read-out circuit 260 as the Vs level between times t2 and t3. Meanwhile, the potential of the node n10 corresponding to the power supply potential VDD is read out to the read-out circuit 260 as the Vr level between times t4 and t5. Accordingly, the difference between the potential at the Vs level and the potential at the Vr level is generated as the threshold potential Vth of the pixel 250. The memory 280 stores the threshold potential Vth for each coordinate (x, y) of the pixel circuit 250. Since the capacity of the first electricity accumulation unit 102 is known, the remaining electric charge amount corresponding to 1 count of the counter 105 can be accurately calculated from the information concerning the threshold potential Vth and the capacity of the first electricity accumulation unit 102. Accordingly, the coefficient K1 is calibrated and stored as K1 (x, y) for each coordinate (x, y) of the pixel circuit 250. That is, the image signal G (x, y) of the pixel circuit 250 can be more accurately computed as K1 (x, y)×[the number of reset times]+K2×K4×[the signal value of the digital remaining electric charge signal Sa1].

As described above, according to the present embodiment, in the normal mode, the electric charges generated by the electric conversion element 101a are accumulated in the first accumulation unit 102 and the second accumulation unit 109, and each time the comparator 103a becomes the predetermined threshold potential Vth, the first signal is output to reset the first accumulation unit 102, and the counter 105a adds 1 to the count value. Accordingly, even in the case where the electric charges generated by the electric conversion element 101a exceed the capacity of the first accumulation unit 102, the accumulation of the electric charges in the first accumulation unit 102 can be continued, and the electric charge amount generated by the electric conversion element 101a can also be calculated from the count value.

In addition, in the read-out of the first Vr level and Vs level, the remaining electric charges of the electric conversion element 101a can be read out as a signal of high SN by CDS driving. On the other hand, in the read-out of the second Vr level and Vs level, the remaining electric charges of the electric conversion element 101a and the remaining electric charges of the first accumulation unit 102 and the second accumulation unit 109 can be read out by DDS driving. In addition, since the electric charges generated by the photoelectric conversion element 101a in the reset period of the first accumulation unit 102 are continuously accumulated by the second accumulation unit 109, the electric charges generated by the photoelectric conversion element 101a in the reset period of the first accumulation unit 102 are also included in the remaining electric charges in the read-out of the second Vr level and Vs level. Accordingly, the image signal G (x, y) including the electric charges generated by the photoelectric conversion element 101a in the reset period of the first accumulation unit 102 can be generated.

As in the above case, even in the case where the capacity of the first accumulation unit 102 is never exceeded with low irradiation, the remaining electric charges of the electric conversion element 101a can be read out as a signal of high SN by CDS driving in the read-out of the first Vr level and Vs level. On the other hand, the remaining electric charges of the electric conversion element 101a and the remaining electric charges of one accumulation unit 102 and the second accumulation unit 109 can be read out by DDS driving in the read-out of the second Vr level and Vs level.

Further, in the calibration mode, the potential L26 of the transformer power supply VRS is increased from the lower side of the threshold potential Vth. Accordingly, when the potential L26 of the transformer power supply VRS continues to increase, the potential of the node n16 enters a state of exceeding the threshold potential Vth upward, the reset transistor 104a enters a non-conductive state, and the potential of the node n16 is maintained in the state of the threshold potential Vth. At this time, the capacitor connection transistor 115 also becomes a non-conductive state, and the potential of the node n10 is maintained in the state of the threshold potential Vth. Hence, information concerning the threshold potential Vth for each pixel circuit 250 can be obtained, and the coefficient K1 can be calibrated and stored as K1 (x, y) for each coordinate (x, y) of the pixel circuit 250. Accordingly, by the read-out of the first Vr level and Vs level, K1 (x, y)×[the number of reset times]+K4×[the signal value of the digital remaining electric charge signal Sa1] can be more accurately computed as the image signal G (x, y). As similar to the above, by the read-out of the second Vr level and Vs level, K1 (x, y)×[the number of reset times]+K5'[the signal value of the digital remaining electric charge signal Sa2] can be more accurately computed as the image signal G (x, y) of the pixel circuit 250.

### Fourth Embodiment

A solid-state imaging element 200 according to a fourth embodiment is different from the solid-state imaging element 200 according to the third embodiment in that the current supplied from the current source of the comparator 103a can be suppressed in the case where the potential of the second electricity accumulation unit is higher than a predetermined value. Hereinafter, the differences from the solid-state imaging element 200 according to the third embodiment will be described.

### Configuration Example of Pixel Circuit

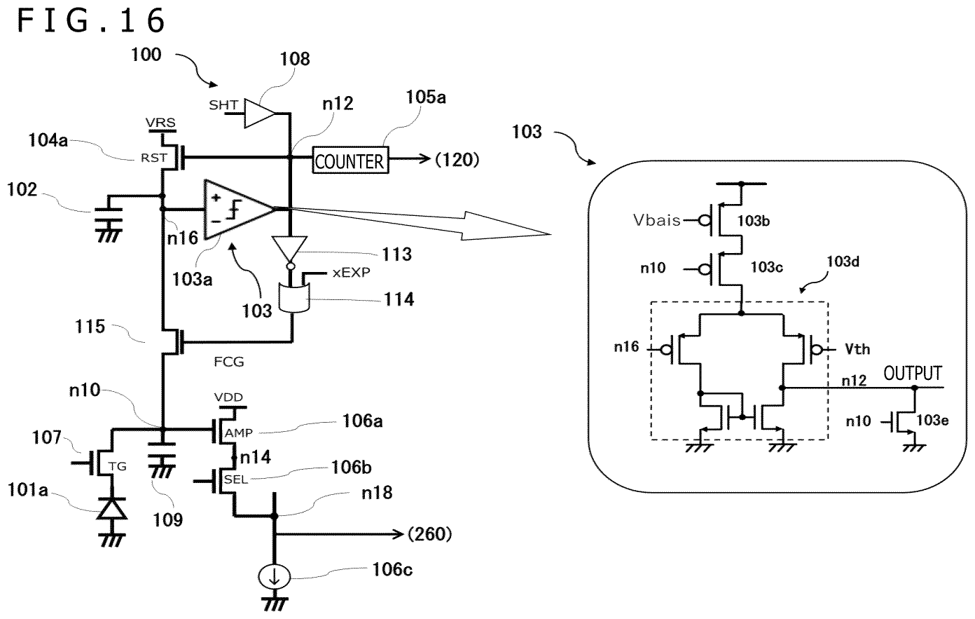

FIG. 16 is a diagram for depicting a configuration example of the pixel circuit 250 according to the fourth embodiment. As depicted in FIG. 16, the determination unit 103 includes a differential amplifier 103d, and a PMOS transistor 103c is provided in series between a constant current bias transistor 103b for determining an operation current and a differential pair.

The gate electrode of the MOS transistor 103c is connected to the second accumulation unit 109 of the node n10. In addition, an NMOS transistor 103e is provided in parallel at the output node, and the gate electrode thereof is also connected to the second accumulation unit 109 of the node n10. By using such a circuit, when the potential of the second accumulation unit 109 is high, the PMOS transistor 103c is turned off, so that no current flows through the determination unit 103. In addition, the NMOS transistor 103e is turned on, and the output potential is fixed at the Lo potential.

### Operation Example in Normal Mode

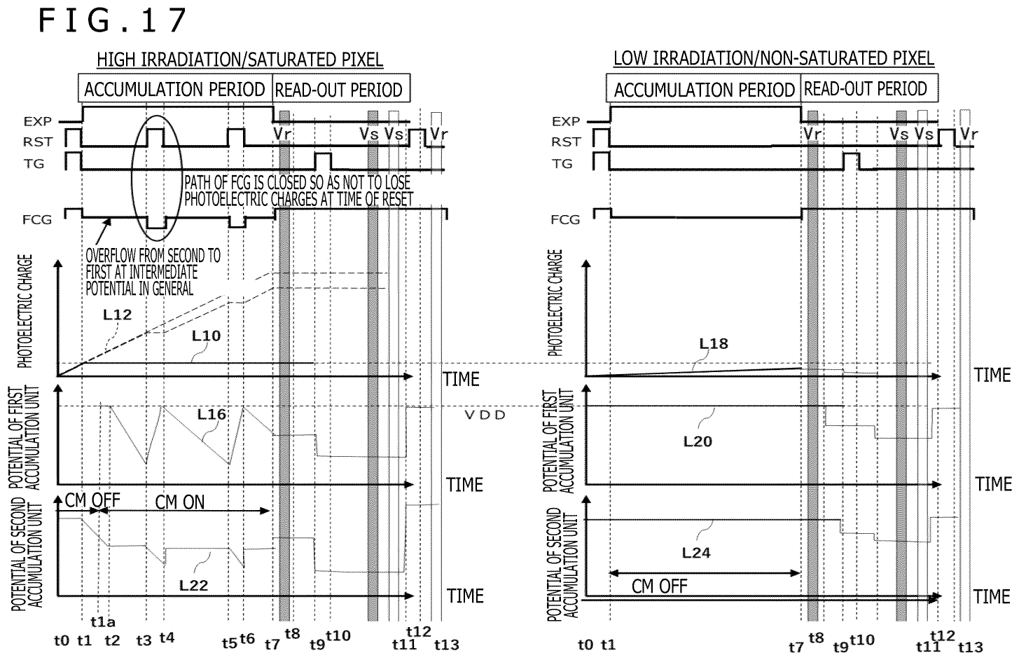

FIG. 17 depicts time charts of an operation example according to the fourth embodiment. The explainer of the basic operation is similar to that in m FIG. 14. Between times to and t1a, since the potential of the second accumulation unit 109 is higher than a predetermined value, the PMOS transistor 103c is turned off, and no current flows through the determination unit 103.

Meanwhile, between times t1a and t7, since the potential of the second accumulation unit 109 is lower than the predetermined value, the PMOS transistor 103c is turned on, and a current flows through the determination unit 103. In such a way, since the supply current during the period when the determination unit 103 is not used can be suppressed, the power consumption of the imaging element 250 can be suppressed.

As similar to the above, in the case of low illuminance, since the potential of the second accumulation unit 109 does not become lower than the predetermined value, the PMOS transistor 103c is turned off in the entire imaging period, and a state in which no current flows through the determination unit 103 is maintained.

As described above, according to the present embodiment, the PMOS transistor 103c is provided in series between the constant current bias transistor 103b for determining the operation current of the determination unit 103 and the differential pair, and the gate electrode of the PMOS transistor 103c is connected to the second accumulation unit 109 of the node n10. Accordingly, in the case where the second accumulation unit 109 is higher than the predetermined potential, the supply power can be suppressed.

### Fifth Embodiment

A solid-state imaging element 200 according to a fifth embodiment is different from the solid-state imaging element 200 according to the first embodiment in that a comparator 300, a counter 261, and a latch in a column signal processing unit 160 are configured for each pixel circuit 250. Hereinafter, the differences from the solid-state imaging element 200 according to the first embodiment will be described.

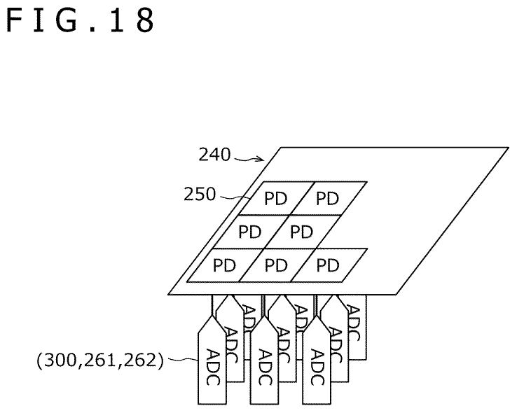

FIG. 18 is a diagram for schematically depicting a part of the imaging element 200. As depicted in FIG. 18, the comparator 300, the counter 261, and the latch in the column signal processing unit 160 are configured for each pixel circuit 250. In addition, the comparator 300 may be shared as the comparator 103a (see FIG. 6). In such a way, the circuit scale can be reduced, and the area can be reduced.

### 1. Application Example

The technique according to the present disclosure can be applied to various products. For example, the technique according to the present disclosure may be realized as a device mounted on any kind of mobile body such as an automobile, an electric automobile, a hybrid electric automobile, a motorcycle, a bicycle, a personal mobility, an airplane, a drone, a ship, a robot, a construction machine, and an agricultural machine (tractor).

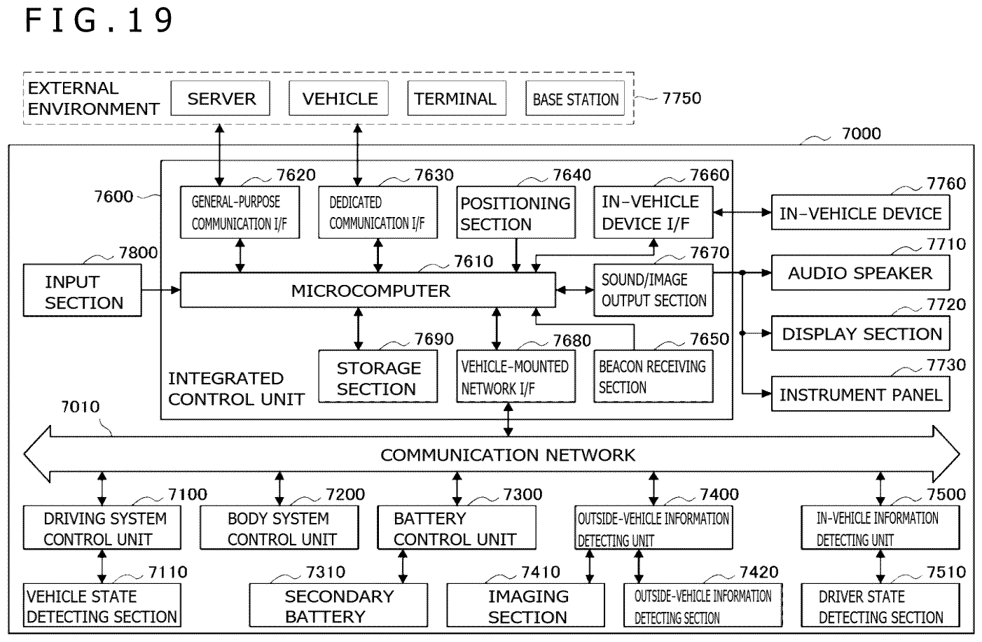

FIG. 19 is a block diagram depicting an example of schematic configuration of a vehicle control system 7000 as an example of a mobile body control system to which the technology according to an embodiment of the present disclosure can be applied. The vehicle control system 7000 includes a plurality of electronic control units connected to each other via a communication network 7010. In the example depicted in FIG. 19, the vehicle control system 7000 includes a driving system control unit 7100, a body system control unit 7200, a battery control unit 7300, an outside-vehicle information detecting unit 7400, an in-vehicle information detecting unit 7500, and an integrated control unit 7600. The communication network 7010 connecting the plurality of control units to each other may, for example, be a vehicle-mounted communication network compliant with an arbitrary standard such as controller area network (CAN), local interconnect network (LIN), local area network (LAN), FlexRay (registered trademark), or the like.

Each of the control units includes: a microcomputer that performs arithmetic processing according to various kinds of programs; a storage section that stores the programs executed by the microcomputer, parameters used for various kinds of operations, or the like; and a driving circuit that drives various kinds of control target devices. Each of the control units further includes: a network interface (I/F) for performing communication with other control units via the communication network 7010; and a communication I/F for performing communication with a device, a sensor, or the like within and without the vehicle by wire communication or radio communication. A functional configuration of the integrated control unit 7600 illustrated in FIG. 19 includes a microcomputer 7610, a general-purpose communication I/F 7620, a dedicated communication I/F 7630, a positioning section 7640, a beacon receiving section 7650, an in-vehicle device I/F 7660, a sound/image output section 7670, a vehicle-mounted network I/F 7680, and a storage section 7690. The other control units similarly include a microcomputer, a communication I/F, a storage section, and the like.

The driving system control unit 7100 controls the operation of devices related to the driving system of the vehicle in accordance with various kinds of programs. For example, the driving system control unit 7100 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like. The driving system control unit 7100 may have a function as a control device of an antilock brake system (ABS), electronic stability control (ESC), or the like.

The driving system control unit 7100 is connected with a vehicle state detecting section 7110. The vehicle state detecting section 7110, for example, includes at least one of a gyro sensor that detects the angular velocity of axial rotational movement of a vehicle body, an acceleration sensor that detects the acceleration of the vehicle, and sensors for detecting an amount of operation of an accelerator pedal, an amount of operation of a brake pedal, the steering angle of a steering wheel, an engine speed or the rotational speed of wheels, and the like. The driving system control unit 7100 performs arithmetic processing using a signal input from the vehicle state detecting section 7110, and controls the internal combustion engine, the driving motor, an electric power steering device, the brake device, and the like.

The body system control unit 7200 controls the operation of various kinds of devices provided to the vehicle body in accordance with various kinds of programs. For example, the body system control unit 7200 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 7200. The body system control unit 7200 receives these input radio waves or signals, and controls a door lock device, the power window device, the lamps, or the like of the vehicle.

The battery control unit 7300 controls a secondary battery 7310, which is a power supply source for the driving motor, in accordance with various kinds of programs. For example, the battery control unit 7300 is supplied with information about a battery temperature, a battery output voltage, an amount of charge remaining in the battery, or the like from a battery device including the secondary battery 7310. The battery control unit 7300 performs arithmetic processing using these signals, and performs control for regulating the temperature of the secondary battery 7310 or controls a cooling device provided to the battery device or the like.

The outside-vehicle information detecting unit 7400 detects information about the outside of the vehicle including the vehicle control system 7000. For example, the outside-vehicle information detecting unit 7400 is connected with at least one of an imaging section 7410 and an outside-vehicle information detecting section 7420. The imaging section 7410 includes at least one of a time-of-flight (ToF) camera, a stereo camera, a monocular camera, an infrared camera, and other cameras. The outside-vehicle information detecting section 7420, for example, includes at least one of an environmental sensor for detecting current atmospheric conditions or weather conditions and a peripheral information detecting sensor for detecting another vehicle, an obstacle, a pedestrian, or the like on the periphery of the vehicle including the vehicle control system 7000.

The environmental sensor, for example, may be at least one of a rain drop sensor detecting rain, a fog sensor detecting a fog, a sunshine sensor detecting a degree of sunshine, and a snow sensor detecting a snowfall. The peripheral information detecting sensor may be at least one of an ultrasonic sensor, a radar device, and a LIDAR device (Light detection and Ranging device, or Laser imaging detection and ranging device). Each of the imaging section 7410 and the outside-vehicle information detecting section 7420 may be provided as an independent sensor or device, or may be provided as a device in which a plurality of sensors or devices are integrated.

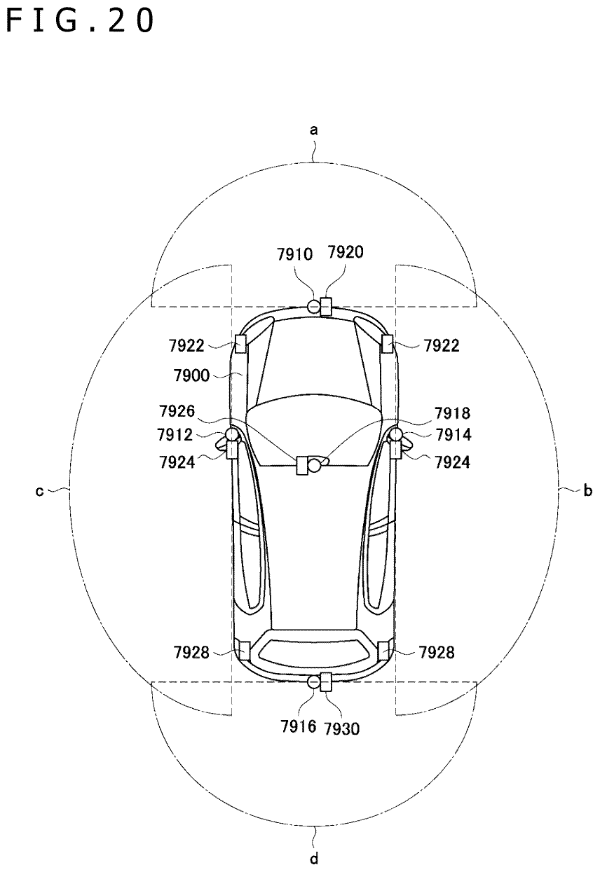

FIG. 20 depicts an example of installation positions of the imaging section 7410 and the outside-vehicle information detecting section 7420. Imaging sections 7910, 7912, 7914, 7916, and 7918 are, for example, disposed at at least one of positions on a front nose, sideview mirrors, a rear bumper, and a back door of the vehicle 7900 and a position on an upper portion of a windshield within the interior of the vehicle. The imaging section 7910 provided to the front nose and the imaging section 7918 provided to the upper portion of the windshield within the interior of the vehicle obtain mainly an image of the front of the vehicle 7900. The imaging sections 7912 and 7914 provided to the sideview mirrors obtain mainly an image of the sides of the vehicle 7900. The imaging section 7916 provided to the rear bumper or the back door obtains mainly an image of the rear of the vehicle 7900. The imaging section 7918 provided to the upper portion of the windshield within the interior of the vehicle is used mainly to detect a preceding vehicle, a pedestrian, an obstacle, a signal, a traffic sign, a lane, or the like.

Incidentally, FIG. 20 depicts an example of photographing ranges of the respective imaging sections 7910, 7912, 7914, and 7916. An imaging range a represents the imaging range of the imaging section 7910 provided to the front nose. Imaging ranges b and c respectively represent the imaging ranges of the imaging sections 7912 and 7914 provided to the sideview mirrors. An imaging range d represents the imaging range of the imaging section 7916 provided to the rear bumper or the back door. A bird's-eye image of the vehicle 7900 as viewed from above can be obtained by superimposing image data imaged by the imaging sections 7910, 7912, 7914, and 7916, for example.

Outside-vehicle information detecting sections 7920, 7922, 7924, 7926, 7928, and 7930 provided to the front, rear, sides, and corners of the vehicle 7900 and the upper portion of the windshield within the interior of the vehicle may be, for example, an ultrasonic sensor or a radar device. The outside-vehicle information detecting sections 7920, 7926, and 7930 provided to the front nose of the vehicle 7900, the rear bumper, the back door of the vehicle 7900, and the upper portion of the windshield within the interior of the vehicle may be a LIDAR device, for example. These outside-vehicle information detecting sections 7920 to 7930 are used mainly to detect a preceding vehicle, a pedestrian, an obstacle, or the like.

Returning to FIG. 19, the description will be continued. The outside-vehicle information detecting unit 7400 makes the imaging section 7410 image an image of the outside of the vehicle, and receives imaged image data. In addition, the outside-vehicle information detecting unit 7400 receives detection information from the outside-vehicle information detecting section 7420 connected to the outside-vehicle information detecting unit 7400. In a case where the outside-vehicle information detecting section 7420 is an ultrasonic sensor, a radar device, or a LIDAR device, the outside-vehicle information detecting unit 7400 transmits an ultrasonic wave, an electromagnetic wave, or the like, and receives information of a received reflected wave. On the basis of the received information, the outside-vehicle information detecting unit 7400 may perform processing of detecting an object such as a human, a vehicle, an obstacle, a sign, a character on a road surface, or the like, or processing of detecting a distance thereto. The outside-vehicle information detecting unit 7400 may perform environment recognition processing of recognizing a rainfall, a fog, road surface conditions, or the like on the basis of the received information. The outside-vehicle information detecting unit 7400 may calculate a distance to an object outside the vehicle on the basis of the received information.

In addition, on the basis of the received image data, the outside-vehicle information detecting unit 7400 may perform image recognition processing of recognizing a human, a vehicle, an obstacle, a sign, a character on a road surface, or the like, or processing of detecting a distance thereto. The outside-vehicle information detecting unit 7400 may subject the received image data to processing such as distortion correction, alignment, or the like, and combine the image data imaged by a plurality of different imaging sections 7410 to generate a bird's-eye image or a panoramic image. The outside-vehicle information detecting unit 7400 may perform viewpoint conversion processing using the image data imaged by the imaging section 7410 including the different imaging parts.

The in-vehicle information detecting unit 7500 detects information about the inside of the vehicle. The in-vehicle information detecting unit 7500 is, for example, connected with a driver state detecting section 7510 that detects the state of a driver. The driver state detecting section 7510 may include a camera that images the driver, a biosensor that detects biological information of the driver, a microphone that collects sound within the interior of the vehicle, or the like. The biosensor is, for example, disposed in a seat surface, the steering wheel, or the like, and detects biological information of an occupant sitting in a seat or the driver holding the steering wheel. On the basis of detection information input from the driver state detecting section 7510, the in-vehicle information detecting unit 7500 may calculate a degree of fatigue of the driver or a degree of concentration of the driver, or may determine whether the driver is dozing. The in-vehicle information detecting unit 7500 may subject an audio signal obtained by the collection of the sound to processing such as noise canceling processing or the like.

The integrated control unit 7600 controls general operation within the vehicle control system 7000 in accordance with various kinds of programs. The integrated control unit 7600 is connected with an input section 7800. The input section 7800 is implemented by a device capable of input operation by an occupant, such, for example, as a touch panel, a button, a microphone, a switch, a lever, or the like. The integrated control unit 7600 may be supplied with data obtained by voice recognition of voice input through the microphone. The input section 7800 may, for example, be a remote control device using infrared rays or other radio waves, or an external connecting device such as a mobile telephone, a personal digital assistant (PDA), or the like that supports operation of the vehicle control system 7000. The input section 7800 may be, for example, a camera. In that case, an occupant can input information by gesture. Alternatively, data may be input which is obtained by detecting the movement of a wearable device that an occupant wears. Further, the input section 7800 may, for example, include an input control circuit or the like that generates an input signal on the basis of information input by an occupant or the like using the above-described input section 7800, and which outputs the generated input signal to the integrated control unit 7600. An occupant or the like inputs various kinds of data or gives an instruction for processing operation to the vehicle control system 7000 by operating the input section 7800.

The storage section 7690 may include a read only memory (ROM) that stores various kinds of programs executed by the microcomputer and a random access memory (RAM) that stores various kinds of parameters, operation results, sensor values, or the like. In addition, the storage section 7690 may be implemented by a magnetic storage device such as a hard disc drive (HDD) or the like, a semiconductor storage device, an optical storage device, a magneto-optical storage device, or the like.

The general-purpose communication I/F 7620 is a communication I/F used widely, which communication I/F mediates communication with various apparatuses present in an external environment 7750. The general-purpose communication I/F 7620 may implement a cellular communication protocol such as global system for mobile communications (GSM (registered trademark)), worldwide interoperability for microwave access (WiMAX (registered trademark)), long term evolution (LTE (registered trademark)), LTE-advanced (LTE-A), or the like, or another wireless communication protocol such as wireless LAN (referred to also as wireless fidelity (Wi-Fi (registered trademark)), Bluetooth (registered trademark), or the like. The general-purpose communication I/F 7620 may, for example, connect to an apparatus (for example, an application server or a control server) present on an external network (for example, the Internet, a cloud network, or a company-specific network) via a base station or an access point. In addition, the general-purpose communication I/F 7620 may connect to a terminal present in the vicinity of the vehicle (which terminal is, for example, a terminal of the driver, a pedestrian, or a store, or a machine type communication (MTC) terminal) using a peer to peer (P2P) technology, for example.

The dedicated communication I/F 7630 is a communication I/F that supports a communication protocol developed for use in vehicles. The dedicated communication I/F 7630 may implement a standard protocol such, for example, as wireless access in vehicle environment (WAVE), which is a combination of institute of electrical and electronic engineers (IEEE) 802.11p as a lower layer and IEEE 1609 as a higher layer, dedicated short range communications (DSRC), or a cellular communication protocol. The dedicated communication I/F 7630 typically carries out V2X communication as a concept including one or more of communication between a vehicle and a vehicle (Vehicle to Vehicle), communication between a road and a vehicle (Vehicle to Infrastructure), communication between a vehicle and a home (Vehicle to Home), and communication between a pedestrian and a vehicle (Vehicle to Pedestrian).

The positioning section 7640, for example, performs positioning by receiving a global navigation satellite system (GNSS) signal from a GNSS satellite (for example, a GPS signal from a global positioning system (GPS) satellite), and generates positional information including the latitude, longitude, and altitude of the vehicle. Incidentally, the positioning section 7640 may identify a current position by exchanging signals with a wireless access point, or may obtain the positional information from a terminal such as a mobile telephone, a personal handyphone system (PHS), or a smart phone that has a positioning function.

The beacon receiving section 7650, for example, receives a radio wave or an electromagnetic wave transmitted from a radio station installed on a road or the like, and thereby obtains information about the current position, congestion, a closed road, a necessary time, or the like. Incidentally, the function of the beacon receiving section 7650 may be included in the dedicated communication I/F 7630 described above.

The in-vehicle device I/F 7660 is a communication interface that mediates connection between the microcomputer 7610 and various in-vehicle devices 7760 present within the vehicle. The in-vehicle device I/F 7660 may establish wireless connection using a wireless communication protocol such as wireless LAN, Bluetooth (registered trademark), near field communication (NFC), or wireless universal serial bus (WUSB). In addition, the in-vehicle device I/F 7660 may establish wired connection by universal serial bus (USB), high-definition multimedia interface (HDMI (registered trademark)), mobile high-definition link (MHL), or the like via a connection terminal (and a cable if necessary) not depicted in the figures. The in-vehicle devices 7760 may, for example, include at least one of a mobile device and a wearable device possessed by an occupant and an information device carried into or attached to the vehicle. The in-vehicle devices 7760 may also include a navigation device that searches for a path to an arbitrary destination. The in-vehicle device I/F 7660 exchanges control signals or data signals with these in-vehicle devices 7760.

The vehicle-mounted network I/F 7680 is an interface that mediates communication between the microcomputer 7610 and the communication network 7010. The vehicle-mounted network I/F 7680 transmits and receives signals or the like in conformity with a predetermined protocol supported by the communication network 7010.

The microcomputer 7610 of the integrated control unit 7600 controls the vehicle control system 7000 in accordance with various kinds of programs on the basis of information obtained via at least one of the general-purpose communication I/F 7620, the dedicated communication I/F 7630, the positioning section 7640, the beacon receiving section 7650, the in-vehicle device I/F 7660, and the vehicle-mounted network I/F 7680. For example, the microcomputer 7610 may calculate a control target value for the driving force generating device, the steering mechanism, or the braking device on the basis of the obtained information about the inside and outside of the vehicle, and output a control command to the driving system control unit 7100. For example, the microcomputer 7610 may perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like. In addition, the microcomputer 7610 may perform cooperative control intended for automated driving, which makes the vehicle to travel automatedly without depending on the operation of the driver, or the like, by controlling the driving force generating device, the steering mechanism, the braking device, or the like on the basis of the obtained information about the surroundings of the vehicle.

The microcomputer 7610 may generate three-dimensional distance information between the vehicle and an object such as a surrounding structure, a person, or the like, and generate local map information including information about the surroundings of the current position of the vehicle, on the basis of information obtained via at least one of the general-purpose communication I/F 7620, the dedicated communication I/F 7630, the positioning section 7640, the beacon receiving section 7650, the in-vehicle device I/F 7660, and the vehicle-mounted network I/F 7680. In addition, the microcomputer 7610 may predict danger such as collision of the vehicle, approaching of a pedestrian or the like, an entry to a closed road, or the like on the basis of the obtained information, and generate a warning signal. The warning signal may, for example, be a signal for producing a warning sound or lighting a warning lamp.

The sound/image output section 7670 transmits an output signal of at least one of a sound and an image to an output device capable of visually or auditorily notifying information to an occupant of the vehicle or the outside of the vehicle. In the example of FIG. 19, an audio speaker 7710, a display section 7720, and an instrument panel 7730 are illustrated as the output device. The display section 7720 may, for example, include at least one of an on-board display and a head-up display. The display section 7720 may have an augmented reality (AR) display function. The output device may be other than these devices, and may be another device such as headphones, a wearable device such as an eyeglass type display worn by an occupant or the like, a projector, a lamp, or the like. In a case where the output device is a display device, the display device visually displays results obtained by various kinds of processing performed by the microcomputer 7610 or information received from another control unit in various forms such as text, an image, a table, a graph, or the like. In addition, in a case where the output device is an audio output device, the audio output device converts an audio signal constituted of reproduced audio data or sound data or the like into an analog signal, and auditorily outputs the analog signal.

Incidentally, at least two control units connected to each other via the communication network 7010 in the example depicted in FIG. 19 may be integrated into one control unit. Alternatively, each individual control unit may include a plurality of control units. Further, the vehicle control system 7000 may include another control unit not depicted in the figures. In addition, part or the whole of the functions performed by one of the control units in the above description may be assigned to another control unit. That is, predetermined arithmetic processing may be performed by any of the control units as long as information is transmitted and received via the communication network 7010. Similarly, a sensor or a device connected to one of the control units may be connected to another control unit, and a plurality of control units may mutually transmit and receive detection information via the communication network 7010.

It should be noted that the computer program for realizing each function of the solid-state imaging device 1 according to the present embodiment described using FIG. 1 can be implemented in any control unit or the like. In addition, it is also possible to provide a computer-readable recording medium in which such a computer program is stored. The recording medium is, for example, a magnetic disk, an optical disk, a magneto-optical disk, a flash memory, or the like. In addition, the above-described computer program may be distributed via, for example, a network without using a recording medium.

In the vehicle control system 7000 described above, the solid-state imaging device 1 according to the present embodiment described using FIG. 1 can be applied to the imaging section 7410 of the application example depicted in FIG. 19. For example, the dynamic range of the imaging section 7410 can be enlarged.

It should be noted that the present technique can be configured as follows.

(1)

A solid-state imaging element including:

a photoelectric conversion unit that generates electric charges according to an amount of received light;

a first electricity accumulation unit that is connected to the photoelectric conversion unit via a first node;

a comparator that outputs a first signal when a potential of the first node and a predetermined potential coincide with each other;

a reset unit that sets the first node to a reset potential according to the first signal; and

a counting unit that counts and outputs the first signal,

in which, in a first mode, the reset potential applied to the first node changes in time series.

(2)

The solid-state imaging element according to (1),

in which, in a second mode, the reset potential having a fixed value is applied.

(3)

The solid-state imaging element according to (2),

in which the reset unit includes a reset transistor connected between the first node and a power supply unit,

the comparator maintains an output of the first signal in a case where the potential of the first node exceeds the predetermined potential to a low potential side,

the reset unit causes the reset transistor to be in a conductive state during the output of the first signal, and,

in the first mode, the potential of the power supply unit is so raised as to exceed the predetermined potential from the low potential side relative to the predetermined potential.

(4)

The solid-state imaging element according to (3), further including:

a readout circuit that reads out the potential of the first node.

(5)

The solid-state imaging element according to (4), further including:

an analog-digital conversion unit that generates a digital signal in reference to an analog signal supplied from the readout circuit; and

a signal processing unit that generates an image signal corresponding to an electric charge amount generated by the photoelectric conversion unit, according to the count, the digital signal, and a predetermined coefficient.

(6)

The solid-state imaging element according to (5),

in which the signal processing unit changes a value of the predetermined coefficient in reference to the digital signal obtained in the first mode.

(7)

The solid-state imaging element according to (5),

in which, in the first mode, a plurality of potentials that are different in speed at which the potential applied to the first node changes in time series are applied, and a plurality of the predetermined coefficients are generated in reference to a plurality of the digital signals, and,

in the second mode, the signal processing unit changes the value of the predetermined coefficient in reference to the plurality of digital signals.

(8)

The solid-state imaging element according to (7),

in which, in the second mode, the signal processing unit changes the value of the predetermined coefficient according to the count.

(9)

The solid-state imaging element according to (8), further including:

a second electricity accumulation unit that is connected to the first node in parallel with the first electricity accumulation unit.

(10)

The solid-state imaging element according to (9),

in which the first electricity accumulation unit is connected to the first node via a second transistor,

in a first period of the second mode, the conductive state of the second transistor is set to a first state, and,

in a case where the electric charges accumulated in the second electricity accumulation unit exceed a predetermined capacity, the electric charges are accumulated in the first electricity accumulation unit.

(11)

The solid-state imaging element according to (10),

in which, in the first mode, the second transistor enters a state of higher conductivity than the first state during the output of the first signal, and enters a non-conductive state when the output of the first signal is stopped, and,

in the second mode, the signal processing unit changes the value of the predetermined coefficient in reference to the digital signal obtained in the non-conductive state in the first mode.

(12)

The solid-state imaging element according to (11),

in which a current to be supplied to the comparator is controlled according to the potential of the second electricity accumulation unit.

(13)

A solid-state imaging device including:

the solid-state imaging element according to (1); and

an optical system.

Aspects of the present disclosure are not limited to the individual embodiments described above, and include various modifications at which those skilled in the art can arrive, and the effects of the present disclosure are also not limited to the contents described above. That is, various additions, changes, and partial deletions are possible without departing from the conceptual idea and gist of the present disclosure derived from the contents defined in the claims and equivalents thereof.

### REFERENCE SIGNS LIST

1: Imaging device
101: Photoelectric conversion unit
102: First electricity accumulation unit
Comparator 103a
104: Reset unit
104a: Reset transistor
105: Counting unit
107: Transfer transistor
109: Second electricity accumulation unit
115: Capacitor connection transistor
200: Solid-state imaging element
260: Readout circuit
280: Signal processing unit

1. A solid-state imaging element comprising:
a photoelectric conversion unit that generates electric charges according to an amount of received light;
a first electric charge holding unit that is connected to the photoelectric conversion unit via a first node;
a comparator that outputs a first signal when a potential of the first node and a predetermined potential coincide with each other;
a reset unit that sets the first node to a reset potential according to the first signal; and
a counting unit that counts and outputs the first signal,
wherein, in a first mode, the reset potential applied to the first node changes in time series.

2. The solid-state imaging element according to claim 1,
wherein, in a second mode, the reset potential having a fixed value is applied.

3. The solid-state imaging element according to claim 1,
wherein the reset unit includes a reset transistor connected between the first node and a power supply unit,
the comparator maintains an output of the first signal in a case where the potential of the first node exceeds the predetermined potential to a low potential side,
the reset unit causes the reset transistor to be in a conductive state during the output of the first signal, and,
in the first mode, the potential of the power supply unit is so raised as to exceed the predetermined potential from the low potential side relative to the predetermined potential.

4. The solid-state imaging element according to claim 3, further comprising:
a readout circuit that reads out the potential of the first node.

5. The solid-state imaging element according to claim 4, further comprising:
an analog-digital conversion unit that generates a digital signal in reference to an analog signal supplied from the readout circuit; and
a signal processing unit that generates an image signal corresponding to an electric charge amount generated by the photoelectric conversion unit, according to the count, the digital signal, and a predetermined coefficient.

6. The solid-state imaging element according to claim 5,
wherein the signal processing unit changes a value of the predetermined coefficient in reference to the digital signal obtained in the first mode.

7. The solid-state imaging element according to claim 5,
wherein, in the first mode, a plurality of potentials that are different in speed at which the potential applied to the first node changes in time series are applied, and a plurality of the predetermined coefficients are generated in reference to a plurality of the digital signals, and,
in the second mode, the signal processing unit changes the value of the predetermined coefficient in reference to the plurality of digital signals.

8. The solid-state imaging element according to claim 7,
wherein, in the second mode, the signal processing unit changes the value of the predetermined coefficient according to the count.

9. The solid-state imaging element according to claim 8, further comprising:
a second electric charge holding unit that is connected to the first node in parallel with the first electric charge holding unit.

10. The solid-state imaging element according to claim 9,
wherein the first electric charge holding unit is connected to the first node via a second transistor,
in a first period of the second mode, the conductive state of the second transistor is set to a first state, and,
in a case where the electric charges accumulated in the second electric charge holding unit exceed a predetermined capacity, the electric charges are accumulated in the first electric charge holding unit.

11. The solid-state imaging element according to claim 10,
wherein, in the first mode, the second transistor enters a state of higher conductivity than the first state during the output of the first signal, and enters a non-conductive state when the output of the first signal is stopped, and,
in the second mode, the signal processing unit changes the value of the predetermined coefficient in reference to the digital signal obtained in the non-conductive state in the first mode.

12. The solid-state imaging element according to claim 11,
wherein a current to be supplied to the comparator is controlled according to the potential of the second electric charge holding unit.

13. A solid-state imaging device comprising:
the solid-state imaging element according to claim 1; and
an optical system.
